(19) United States
(12) Patent Application Publication
(10) Pub. No.: US 2011/0284075 A1
(43) Pub. Date: Nov. 24, 2011

(54) POLYMER SHEET FOR SOLAR CELL BACK SHEET, METHOD FOR PRODUCING THE SAME, AND SOLAR CELL MODULE

(75) Inventors: Akira HATAKEYAMA, Kanagawa (JP); Shinji TANAKA, Kanagawa (JP); Yusuke AKASAKI, Kanagawa (JP); Yohei ARITOSHI, Kanagawa (JP)

(73) Assignee: FUJIFILM CORPORATION, Tokyo (JP)

(21) Appl. No.: 13/109,464

(22) Filed: May 17, 2011

(30) Foreign Application Priority Data
May 19, 2010 (JP) 2010-115260
Mar. 25, 2011 (JP) 2011-068888
May 12, 2011 (JP) 2011-107016

(51) Int. Cl. H01L 31/0203; B05D 3/00; B32B 7/02

(52) U.S. Cl. 136/259; 428/213; 427/393.5

(57) ABSTRACT

There is provided a polymer sheet for a solar cell back sheet, which includes a polymer support, an undercoat layer which contains a binder and is provided on at least one surface of the polymer support to a thickness of 0.05 to 10 μm, and a fluorine-containing polymer layer which contains a binder including at least a fluorine-based polymer and is provided in contact with the undercoat layer of the at least one surface of the polymer support, to a thickness of 0.8 to 12 μm.

### CROSS-REFERENCE TO RELATED APPLICATION

This application claims priority under 35 USC 119 from Japanese Patent Applications Nos. 2010-115260, filed on May 19, 2010, 2011-068888, filed on Mar. 25, 2011 and 2011-107016, filed on May 12, 2011, the disclosures of which are incorporated by reference herein.

### BACKGROUND OF THE INVENTION

1. Field of the Invention

The present invention relates to a polymer sheet for solar cell back sheets, a method for producing the polymer sheet, and a solar cell module.

2. Description of the Related Art

Solar cells are power generating systems which do not discharge carbon dioxide during power generation and have little adverse effect on the environment, and in recent years, solar cells have been rapidly popularized.

A solar cell module in general has a structure in which a solar cell is sandwiched between a glass on a side where sunlight enters, and a so-called back sheet that is disposed on a side opposite to a side where sunlight enters (rear surface side). The spaces between the glass and the solar cell and between the solar cell and the back sheet are respectively sealed with an EVA (ethylene-vinyl acetate) resin or the like.

A back sheet has a function of preventing the intrusion of moisture from the rear surface of a solar cell module, and from the viewpoint of cost and the like, polyesters have been used therefor. Furthermore, a back sheet is required not only to have a function of suppressing the penetration of moisture, but also to have durability, light reflecting properties, electrical insulating properties, and the like. The back sheet is constructed by, for example, laminating a layer which enhances weather resistance, or a colored layer which has been imparted with reflection performance by adding white inorganic fine particles of titanium oxide or the like, on a polymer support.

Furthermore, as a back sheet for solar cells which has excellent adhesiveness and the thinner thickness, there has been proposed, for example, a back sheet for solar cells in which a cured coating film of a fluorine-based polymer coating material containing a curable functional group is formed on one surface of a water-impermeable sheet such as a Si-deposited polymer sheet (see Japanese Patent Application Laid-Open (JP-A) No. 2007-35694). Furthermore, there has been suggested a back sheet for solar cells, in which an amorphous fluorocopolymer layer is provided by applying a coating liquid containing a fluorocopolymer, a crosslinking agent and the like (see Japanese Patent Application National Publication (Laid-Open) No. 2010-519742).

A fluorine-containing polymer layer has high weather resistance, and when a back sheet for solar cells having this layer is used, an increase in the service life of solar cell modules may be promoted. However, the fluorine-containing polymer layer is less adhesive, and particularly when used for a long time, the fluorine-containing polymer layer is liable to peel off.

It is an object of the invention to provide a polymer sheet for solar cell back sheets which has a polymer layer having high durability and in which the adhesiveness of the polymer layer is retained for a long time period.

### SUMMARY OF THE INVENTION

The present invention has been made in view of the above circumstances and provides a polymer sheet for solar cell back sheets, a method for producing the polymer sheet, and a solar cell module.

A first aspect of the present invention provides

a polymer sheet for a solar cell back sheet, including:

a polymer support;

an undercoat layer that contains a first binder and that is provided on at least one surface of the polymer support at a thickness of from 0.05 to 10 μm; and

a fluorine-containing polymer layer that contains a second binder including at least a fluorine-based polymer and that is provided in contact with the undercoat layer of the at least one surface of the polymer support, at a thickness of from 0.8 to 12 μm.

A second aspect of the present invention provides

a back sheet for a solar cell, comprising the polymer sheet for a solar cell back sheet of the first aspect of the present invention.

A third aspect of the present invention provides

a solar cell module including the polymer sheet for a solar cell back sheet of the second aspect of the present invention.

A forth aspect of the present invention provides

a method for producing the polymer sheet for a solar cell back sheet of the first aspect of the present invention, the method including:

providing a polymer sheet having the undercoat layer on at least one surface of the polymer support;

applying a coating liquid, which contains the second binder containing a fluorine-based polymer and contains water in an amount of 60% by mass or greater relative to a total amount of solvent, on the undercoat layer; and

forming the fluorine-containing polymer layer by drying the coating liquid applied on the undercoat layer.

### BRIEF DESCRIPTION OF THE DRAWINGS

FIG. 1 is a schematic cross-sectional diagram showing a configuration example of a solar cell module.

### DETAILED DESCRIPTION OF THE INVENTION

According to the invention, there are provided a polymer sheet for solar cell back sheets which has a polymer layer having high durability and in which the adhesiveness of the polymer layer is retained for a long time period, a method for producing the polymer sheet, and a solar cell module.

Hereinafter, the polymer sheet for solar cell back sheets of the invention, a method for producing the polymer sheet, and a solar cell module will be described in detail.

<Polymer Sheet for Solar Cell Back Sheet>

The polymer sheet for solar cell back sheet related to the invention has a polymer support, an undercoat layer provided on at least one surface of the polymer support, and a fluorine-containing polymer layer provided in contact with the undercoat layer on at least one surface of the polymer support. The undercoat layer contains a binder and has a thickness of 0.05 to 10 μm, and the fluorine-containing polymer layer contains a binder which includes at least a fluorine-based polymer, and has a thickness of 0.8 μm to 12 μm. The polymer sheet for solar cell back sheets related to the invention (hereinafter, also simply referred to as “polymer sheet”) is a polymer sheet that may function as a back sheet for solar cells (hereinafter, also simply referred to as “back sheet”).

The polymer sheet of the invention may be constituted of the polymer support, the undercoat layer, and the fluorine-containing polymer layer only, or may also have another layer that is selected as necessary (for example, a colored layer, or a easy adhesive layer) on the surface of the polymer support or on the surface of the fluorine-containing polymer layer, or on both surfaces. The other layer may be a single layer, or may include two or more layers.

—Polymer Support—

Examples of the polymer support (substrate) include supports made of polyesters, polyolefins such as polypropylene and polyethylene, and fluorine-based polymers such as polyvinyl fluoride. Among these, polyesters are preferred, and especially, polyethylene terephthalate is particularly preferred from the viewpoint of the balance between mechanical properties and cost.

The content of carboxyl groups in the polyester that is used as the polymer support of the invention is preferably 55 mol/ton or less, and more preferably 35 mol/ton or less. When the carboxyl group content is 55 mol/ton or less, hydrolysis resistance of the polymer support may be retained, and the decrease in strength of the polymer support that may occur when the polymer support is kept in a lapse of time under heat and moisture, may be lowered. Accordingly, a back sheet for solar cells in which the value of the breaking elongation obtainable after storage for 50 hours under the conditions of 120° C. and 100% RH is 50% or greater of the value of the breaking elongation before storage, is obtained. Hereinafter, the retention rate of the breaking elongation obtainable before and after treatment of a back sheet that has been subjected to a heat-moisture treatment under the relevant conditions, will also be simply referred to as an “retention rate of breaking elongation.” The polymer sheet of the invention is such that the retention rate of breaking elongation is more preferably 60% or greater, and even more preferably 70% or greater.

The lower limit of the carboxyl group content is preferably 2 mol/ton, from the viewpoint of maintaining the adhesiveness between the polymer support and the undercoat layer formed thereon.

The carboxyl group content in the polyester may be adjusted by the kind of the polymerization catalyst, conditions for film formation (temperature or time for film formation), and solid state polymerization.

In order to polymerize a polyester that is used in the polymer support, it is preferable to use a Sb-based, Ge-based or Ti-based compound as a catalyst from the viewpoint of suppressing the carboxyl group content to a predetermined range, and among these, a Ti-based compound is particularly preferred.

It is preferable that the polyester that constitutes the polymer support be polymerized in the solid state after the polymerization of the monomer. Accordingly, a preferable carboxyl group content may be achieved. Solid state polymerization is a technique of increasing the degree of polymerization by heating the polyester obtained after polymerization, to a temperature of about 170° C. to 240° C. for about 5 to 100 hours in a vacuum or in nitrogen gas. Specifically, solid state polymerization may be achieved by applying the methods described in Japanese Patent Nos. 2621563, 3121876, 3136774, 3603585, 3616522, 3617340, 3680523, 3717392, 4167159, and the like.

The polyester used in the polymer support of the invention is preferably a biaxially stretched polyester, from the viewpoint of mechanical strength.

The thickness of the polymer support is preferably about 25 to 300 μm. When the thickness of the support is 25 μm or less, the polymer support has a suitable mechanical strength as a support for solar cell back sheets, and when the thickness is 300 μm or less, it is advantageous in terms of cost.

The polymer support according to the invention is preferably a support formed from a polyester film which has a terminal carboxyl group concentration of from 4.0 mol/ton to 15 mol/ton; a minor endothermic peak temperature Tmeta (° C.) of 220° C. or lower as determined by differential scanning calorimetry (DSC); and an average elongation retention rate obtainable after storage for 72 hours under the conditions of a temperature of 125° C. and relative moisture of 100% RH, of 10% or greater.

Hereinafter, the polyester film that constitutes the polymer support will be described in detail.

<Terminal Carboxyl Group Concentration (AV)>

The terminal carboxyl group concentration (hereinafter, appropriately referred to as “AV”) in the polyester film is from 4.0 mol/ton to 15 mol/ton, more preferably from 6.0 mol/ton to 13 mol/ton, and even more preferably from 7.0 mol/ton to 9 mol/ton.

A terminal carboxyl group has a function of forming hydrogen bonding with a hydroxyl group present on the surface of a member or a layer that is adjacent to the polyester film, and thereby enhancing the adhesive force. For this reason, when the AV is lower than 4.0 mol/ton, the adhesive force decreases. On the other hand, H⁺ in terminal carboxyl groups works as an acid catalyst and has an action of hydrolyzing a polyester molecule. Therefore, with an AV value exceeding 15 mol/ton, when a polyester film is kept for a certain period of time in a high moisture condition, the molecular weight at the surface of the polyester film is decreased due to hydrolysis, and the mechanical strength is decreased. As a result, there occurs peeling (adhesion failure) of the back sheet caused by destruction of the surface of the polyester film.

Examples of a method for specific adjustment of the AV include adjustment of the “plane orientation coefficient” of the polyester film, adjustment of the types and contents of the “constituent components” that constitute the polyester, addition of additives such as a “buffering agent” or a “terminal blocking agent”, and adjustment of the “amount of phosphorus atoms” present in the polyester.

When the AV is adjusted to the range of from 4.0 mol/ton to 15 mol/ton by those specific methods for adjustment, peeling (adhesion failure) of the back sheet due to the hydrolysis of the polyester that is attributable to the terminal carboxyl groups may be suitably suppressed.

Here, among the specific methods for adjustment, when it is intended to adjust the AV to fall in the range of the invention by means of the amount of addition of additives such as a “buffering agent” and a “terminal blocking agent”, and/or the “amount of phosphorus atoms”, it is necessary to increase these contents in the polyester. However, inclusion of an excess amount of additives or phosphorus atoms in a polyester film brings about problems such as precipitation of additives and the like at the support surface in case where the support is kept for a certain period of time under a hot and moisture, or an enhancement of thermal shrinkage due to excessively strong orientation, and eventually causes peeling (adhesion failure) of back sheets. From such viewpoints, it is necessary that the AV of the polyester film according to the invention be from 4.0 mol/ton to 15 mol/ton.

In regard to the polyester raw material (pellet) provided for the formation of a polyester film, it is preferable to adjust the terminal carboxyl group concentration (AV) to the range of 15 mol/ton or less, in order to enhance the hydrolysis resistance. The terminal carboxyl group concentration is preferably 13 mol/ton or less, more preferably 10 mol/ton or less, and most preferably 8 mol/ton or less. The lower limit is not particularly limited, but 0 mol/ton would be the theoretical lower limit. The AV of pellets may be adjusted by the polymerization conditions, the solid state polymerization conditions, and the terminal blocking agent.

A specific method for the measurement of AV will be described below.

<Minor Endothermic Peak Temperature Tmeta (° C.) Determined by Differential Scanning Calorimetry>

A polyester film suitable as the polymer support according to the invention is such that the minor endothermic peak temperature Tmeta (° C.) as determined by a differential scanning calorimetry (hereinafter, also referred to as “DSC”) is 220° C. or lower, preferably from 150° C. to 215° C., and more preferably from 160° C. to 210° C.

The minor endothermic peak temperature Tmeta (° C.) may be adjusted to the range related to the invention by controlling the “plane orientation coefficient” in the polyester film, and the “temperature of the heat fixing carried out after stretching” at the time of forming the polyester film. The temperature of the heat fixing carried out after stretching is preferably from 150° C. to 220° C., more preferably from 160° C. to 210° C., and even more preferably 170° C. to 200° C.

A specific method for the measurement of Tmeta (° C.) will be described below.

<Average Elongation Retention Rate>

The back sheet of the invention has a feature of having high adhesive force even after a lapse of time under a hot and moisture. Therefore, it is preferable that a decrease in the adhesive force be suppressed by suppressing hydrolysis at the surface of the polyester film. From such a viewpoint, the “average elongation retention rate after standing for 72 hours under the conditions of a temperature of 125° C. and relative moisture of 100% RH” is employed as a reference for the hydrolysis at the surface of a polyester support. According to the invention, the average elongation retention rate is preferably 10% or higher.

Here, the term “elongation retention rate” refers to the ratio (%) of the breaking elongation prior to a lapse of time under a hot and moisture (L1) and the breaking elongation after a lapse of time under a hot and moisture (Lt), and is a value determined by the following formula.

Elongation retention rate (%)=100×(Lt)/(Li)

The “average elongation retention rate” according to the invention is obtained by making measurements of the elongation retention rates in the longitudinal direction (MD) and a direction orthogonal thereto (TD) of the polyester film, and expressed as an average value.

Examples of the method for the adjustment of the elongation retention rate include adjustment of the “plane orientation coefficient” of the polyester film, adjustment of the “intrinsic viscosity” of the polyester, adjustment of the types and contents of the “constituent components” that constitute the polyester polymer, addition of additives such as a “buffering agent” or a “terminal blocking agent”, and adjustment of the “amount of phosphorus atoms” present in the polyester.

As a polyester film is more easily hydrolyzable, the polyester film has a smaller molecular weight, and therefore, the value of the average elongation retention rate exhibited by the polyester is likely to be decreased. From such a viewpoint, the polyester film according to the invention is such that the average elongation retention rate needs to be 10% or higher, and is more preferably from 20% to 95%, and even more preferably from 30% to 90%.

When the average elongation retention rate is set at 10% or higher, peeling (adhesion failure) of the back sheet attributable to the hydrolysis of the polyester may be effectively suppressed.

A specific method for the measurement of the average elongation retention rate will be described below.

<Thermal Shrinkage Ratio and Distribution>

In one of suitable embodiments of the polyester film according to the invention, the thermal shrinkage ratios under the conditions of 150° C. and 30 minutes in the longitudinal direction (MD) and in the direction orthogonal thereto (TD) of the polyester film are respectively 1.0% or less, and the thermal shrinkage distributions are respectively from 1% to 20%.

The inventors obtained a finding that adhesion failure of a back sheet due to standing for a certain period of time under a hot and moisture may be caused by the occurrence of thermal shrinkage due to residual strains in the polyester film. That is, it was found that when thermal shrinkage due to residual strains occurs in a polyester film that has been kept for a certain period of time under a hot and moisture, the thermal shrinkage causes the occurrence of shrinkage stress between a sealing material such as EVA and the polyester film, and this shrinkage stress induces adhesion failure of the back sheet.

In the polyester film according to a suitable embodiment of the invention, an effect of suppressing adhesion failure may be enhanced by providing a distribution of thermal shrinkage.

Although still not known clearly, the mechanism is thought to be as follows. That is, when thermal shrinkage in a polyester film is uniform in a film plane, stress also occurs uniformly, and accordingly, the back sheet is easily detachable. On the contrary, as in the case of the polyester film according to a suitable embodiment of the invention, when there is present a distribution in thermal shrinkage, even if there are sites with large thermal shrinkage in the film plane, since there are also sites with small thermal shrinkage in the same plane, thermal shrinkage stops at those sites (that is, shrinkage is not propagated), and the contractile force does not reach a level that is sufficiently large to affect the entire film. Consequently, peeling of the back sheet is suppressed.

A preferred thermal shrinkage distribution of the polyester film according to a suitable embodiment of the invention is from 1% to 20%, and the thermal shrinkage distribution is more preferably from 2% to 15%, and even more preferably from 3% to 12%.

Here, the thermal shrinkage distribution of the polyester film is obtained by making measurements at five points at an interval of 10 cm in the longitudinal direction (MD) and a direction orthogonal thereto (TD), respectively, and determining the thermal shrinkage distributions (%) from the following formula, and the value of a larger distribution is indicated.

Thermal shrinkage distribution (%)=100×(maximum value−minimum value)/average value

If the thermal shrinkage distribution is greater than 20%, the dimensional variation between the sites with large thermal shrinkage and the sites with small thermal shrinkage is too large, and a crater-shaped shrinkage distribution tends to occur. Then, stress concentrations occur along the rim of this crater, and peeling (adhesion failure) is prone to occur. On the other hand, if the thermal shrinkage distribution is less than 1%, the effect of suppressing shrinkage such as described above is difficult to obtain, which is not preferable.

The shrinkage stress does not easily occur in such a polyester film, if the surface area is small. For this reason, the effect of adjusting the thermal shrinkage distribution to the range described above is particularly actualized when the back sheet is bonded to a panel having a large surface area such as 0.5 m² or greater (more preferably 0.75 m² or greater, and even more preferably 1 m² or greater). This is indeed because when the surface area is small, the probability that areas with a large amount of shrinkage and areas with a small amount of shrinkage are co-present is low.

Furthermore, control of such thermal shrinkage ratio and thermal shrinkage distribution is particularly useful in the actualization of the effect of enhancing adhesiveness after a lapse of time under a hot and moisture. That is, thermal shrinkage occurs during a lapse of time under a hot and moisture under high moisture, and in the case of high moisture, adhesion is prone to decrease because water penetrates into the interface of the polyester film and an adjacent member or adjacent layer that is capable of forming hydrogen bonding with the polyester film, cleaving the hydrogen bonding. However, even under such circumstances, since the shrinkage stress due to residual strains may be reduced by regulating the thermal shrinkage and the thermal shrinkage distribution to the ranges described above, it is easy to secure the adhesive force.

The thermal shrinkage ratio of the polyester film according to the invention is measured under the conditions of 150° C. and 30 minutes.

A preferred range of the thermal shrinkage ratio is, both in the longitudinal direction (MD) and a direction orthogonal thereto (TD), preferably 1% or less, more preferably from −0.5% to 0.8, and even more preferably from −0.3% to 0.6% (the symbol “−” used herein means “elongation”).

When the thermal shrinkage ratio is 1% or less, the effect of adjusting the thermal shrinkage distribution to the specific range may be effectively exhibited. If the thermal shrinkage ratio exceeds 1%, the dimensional variation of the polyester film cannot be sufficiently suppressed, and there is a tendency that the effect of adjusting the thermal shrinkage distribution to a specific range may not be obtained. On the other hand, if elongation of the polyester film is achieved to an excessively large extent, there is a tendency that the effect of suppressing the dimensional variation in the polyester film due to the control of the thermal shrinkage distribution may not be obtained.

The thermal shrinkage ratio may be adjusted by performing a heat treatment after stretching during the formation of the polyester film. The temperature of the heat treatment is preferably from 150° C. to 220° C., more preferably from 160° C. to 210° C., and even more preferably from 165° C. to 200° C., and the duration is preferably from 10 seconds to 120 seconds, more preferably from 15 seconds to 90 seconds, and even more preferably from 20 seconds to 60 seconds.

Furthermore, it is preferable to allow relaxation in at least one of the vertical direction and the horizontal direction in addition to the heat treatment after stretching, and the amount of relaxation is preferably from 0.5% to 10%, more preferably from 1.5% to 9%, and even more preferably from 3% to 8%.

The thermal shrinkage distribution may be adjusted by forming a temperature distribution during the process of producing an unstretched film (raw film) by solidifying the polyester film on a cooling roll after the step of melt extrusion performed in the film formation. That is, when a molten body is cooled, spherulites are formed; however, if the cooling rate is varied, a distribution of these spherulites may be formed. This induces an orientation distribution during the vertical and horizontal stretching, and this is expressed as a distribution of the amount of shrinkage. The distribution of the cooling rate of such a molten body may be achieved by providing a temperature distribution to the cooling roll. Such a temperature distribution is achieved by disturbing the flow of a heat medium that is circulated in the cooling roll for temperature regulation, by providing a baffle plate. The temperature distribution is preferably from 0.2° C. to 10° C., more preferably from 0.4° C. to 5° C., and even more preferably from 0.6° C. to 3° C. This temperature distribution may be provided in any direction between the longitudinal direction and the width direction.

Along with the control of such thermal shrinkage ratio and thermal shrinkage distribution, as will be described below, the adhesiveness after a lapse of time under a hot and moisture may be more effectively enhanced by incorporating a “terminal blocking agent” into the polyester, and incorporating a “trifunctional or higher-functional constituent component (C)” as a constituent component of the polyester.

The terminal blocking agent is capable of making the terminal group bulkier by reacting with the polyester, and this serves as an obstacle decreasing the mobility of polyester molecules. In the trifunctional or higher-functional constituent component (C), since the molecule branches via trifunctional group, the mobility of polyester molecules is decreased. As such, when the mobility decreases, the thermal shrinkage distribution may be easily formed. That is, stress occurs in the sites with large thermal shrinkage and the sites with small thermal shrinkage, but the polyester molecules attempt to resolve the stress (strain due to the distribution of thermal shrinkage) by moving under the effect of this stress. At this time, when the mobility decreases as described above, resolution of such a distribution of thermal shrinkage is difficult to occur, and it is easier to form the thermal shrinkage distribution according to the invention.

A specific method for the measurement of thermal shrinkage ratio will be described below.

<Plane Orientation Coefficient and Distribution Thereof>

The polyester film according to the invention preferably has a plane orientation coefficient of 0.165 or greater, more preferably from 0.168 to 0.18, and even more preferably from 0.170 to 0.175. When the plane orientation coefficient is adjusted to 0.165 or greater, the molecules may be oriented, and the formation of the “semicrystalline” portion described above may be promoted, so that hydrolysis resistance may be further enhanced.

Here, the plane orientation coefficient as used herein is measured using an Abbe refractometer and is determined by the following formula (A).

Plane orientation coefficient=(nMD+nTD)/2−nZD (A)

In the formula (A), nMD represents the refractive index in the longitudinal direction (MD) of the film; nTD represents the refractive index in the orthogonal direction (TD) of the film; and nZD represents the refractive index in the film thickness direction.

The plane orientation coefficient of the polyester film may be adjusted by increasing the stretch ratio during the film formation. Preferably, it is desirable to adjust the stretch ratio in the longitudinal direction (MD) of the film as well as the orthogonal direction (TD) of the film to 2.5 to 6.0 times. In order to adjust the plane orientation coefficient of the film to 0.165 or greater, it is preferable to adjust the stretch ratios of the MD and TD respectively to 3.0 to 5.0 times. Furthermore, the plane orientation coefficient may be enhanced by “preheating” and “multistage stretching” (will be described below) during longitudinal stretching.

When the plane orientation coefficient is adjusted to 0.165 or greater, hydrolysis resistance may be suppressed, and adhesion failure due to a decrease in the molecular weight at the surface of the polyester film may be suppressed. Furthermore, the delamination (laminar peeling) caused by excessive progress of the plane orientation may be suppressed, so that the adhesive force may be increased.

According to the invention, it is preferable to provide a distribution to the plane orientation coefficient. The distribution of the plane orientation coefficient is preferably from 1% to 20%, more preferably from 2% to 15%, and even more preferably from 3% to 12%.

The adhesive force may be further enhanced by providing a distribution to the plane orientation coefficient. That is, since the polyester film shrinks after a lapse of time under a hot and moisture, shrinkage stress occurs between the film and a sealing agent such as EVA, and this causes the occurrence of adhesion failure. This thermal shrinkage stress is proportional to the elastic modulus of the film, and this is proportional to the plane orientation coefficient. Therefore, when there exists a distribution in the plane orientation coefficient of the polyester film, a distribution also occurs in the elastic modulus, and thereby sites with high elastic modulus (rigid) and sites with low elastic modulus (soft) are formed. The sites with low elastic modulus have a function of absorbing the thermal shrinkage stress that has occurred, and these sites serve as buffer areas and exhibit an effect of suppressing the decrease in adhesion.

When the distribution of the plane orientation coefficient is less than 1%, there is a tendency that the thermal shrinkage stress may not be relaxed, and the adhesive force may decrease. On the other hand, when the distribution of the plane orientation coefficient is greater than 20%, there is a tendency that the shrinkage stress is excessively concentrated at the sites with less plane orientation, and adhesion failure is prone to occur.

The distribution of the plane orientation coefficient in the polyester film may be formed by adjusting the preheating temperature distribution in the vertical stretching during the formation of the polyester film. That is, by having a preheating temperature distribution, an orientation distribution in the vertical stretching, and a crystal distribution accompanied therewith are formed, and thereby an orientation distribution in the lateral stretching is formed. The temperature distribution as used herein refers to the temperature distribution in the width direction. That is, the temperature distribution formed in the width direction causes the occurrence of a crystal distribution and an orientation distribution in the width direction after vertical stretching. These distributions form orientation unevenness across the entire surface of the film when the polyester film is stretched in the horizontal direction, and thereby a distribution in the plane orientation coefficient is formed.

The distribution of preheating temperature may be adjusted by providing a temperature distribution to the preheating roll. Specifically, it is desirable to adjust the preheating temperature distribution by disturbing the flow of a heat medium that is circulated in the preheating roll for temperature regulation, by providing a baffle plate. The temperature distribution of the preheating temperature is preferably from 0.2° C. to 10° C., more preferably from 0.4° C. to 5° C., and even more preferably from 0.6° C. to 3° C.

Along with such a distribution of the plane orientation coefficient, as will be described below, the adhesiveness after a lapse of time under a hot and moisture may be more effectively enhanced by incorporating a “terminal blocking agent” into the polyester, and incorporating a “trifunctional or higher-functional constituent component (C)” as a constitution component of the invention.

The terminal blocking agent may make the terminal group bulkier by reacting with the polyester, and this serves as an obstacle decreasing the mobility of polyester molecules. In the trifunctional or higher-functional constituent component (C), since the molecule branches via trifunctional group, the mobility of polyester molecules is decreased. As such, when the mobility decreases, the distribution of the plane orientation may be easily formed. That is, stress difference occurs in the sites with large plane orientation and the sites with small plane orientation, thereby causing a creep of molecules to resolve the stress difference. At this time, when the mobility of molecules decreases as described above, resolution of such a distribution of plane orientation is difficult to occur, and it is easier to form the distribution of the plane orientation coefficient.

A specific method for measuring the plane orientation coefficient will be described below.

<Intrinsic Viscosity (IV)>

The polyester film according to the invention preferably has an intrinsic viscosity (hereinafter, appropriately referred to as “IV”) in the range of 0.6 to 1.2 dl/g. The intrinsic viscosity is more preferably 0.65 to 1.0 dl/g, and even more preferably 0.70 to 0.95 dl/g.

If the intrinsic viscosity of the polyester film is less than 0.6 dl/g, the molecules obtain high mobility, and there is a tendency that the distribution of thermal shrinkage or plane orientation described above is prone to be relaxed (resolved). On the other hand, if the intrinsic viscosity is greater than 1.2 dl/g, shear heat generation is likely to occur during melt extrusion, and this accelerates thermal decomposition of the polyester resin. As a result, the amount of carboxylic acid (AV) in the polyester is likely to increase. There is a tendency that this accelerates hydrolysis during the thermal treatment, and the polyester is likely to exhibit adhesion failure.

The IV of the polyester film may be adjusted by the temperature and reaction time employed in the solid state polymerization. According to a suitable aspect of the solid state polymerization, polyester pellets are heat treated in a nitrogen gas stream or in a vacuum, under the temperature conditions of from 180° C. to 250° C., more preferably from 190° C. to 240° C., and even more preferably 195° C. to 230° C., for a period of from 5 hours to 50 hours, more preferably from 10 hours to 40 hours, and even more preferably from 15 hours to 30 hours. The solid state polymerization may be carried out at a constant temperature, or may be carried out at a varying temperature.

Furthermore, in regard to the polyester raw material (pellets) supplied to the formation of the polyester film, it is preferable that the intrinsic viscosity be in the range of 0.6 to 1.2 dl/g, in order to satisfy hydrolysis resistance. The intrinsic viscosity is more preferably 0.65 to 0.10 dl/g, and even more preferably 0.70 to 0.95 dl/g. In order to enhance hydrolysis resistance, it is preferable to increase the intrinsic viscosity; however, when the intrinsic viscosity is greater than 1.2 dl/g, it is needed to lengthen the solid state polymerization time during the production of the polyester resin, and the cost is markedly increased, which is therefore not preferable. Furthermore, if the intrinsic viscosity is smaller than 0.6 dl/g, since the degree of polymerization is low, heat resistance and hydrolysis resistance are markedly decreased, and therefore, it is not preferable. The intrinsic viscosity of the pellet may be adjusted to the preferred range described above, by adjusting the polymerization conditions used at the time of the production of the polyester resin, and the solid state polymerization conditions.

A specific method for measuring the IV will be described below.

<Surface Resistance>

The polyester film according to the invention is such that the surface resistance R₀ of at least one surface is preferably from 10⁶Ω/□ to 10¹⁴Ω/□. The surface resistance R₀ is more preferably from 10⁸Ω/□ to 10¹³Ω/□, and even more preferably from 10⁹Ω/□ to 10¹²Ω/□.

A specific method for measuring the surface resistance R₀ will be described below.

When dust adheres to the surface of the polyester film, a gap occurs at the interface between the polyester film and the EVA (sealing agent) bonded thereon, and the adhesive force is decreased. However, when the surface resistance of the polyester film is adjusted to the range described above, the generation of static electricity may be suppressed, and the adhesion of dust to the polyester film surface caused by the generation of static electricity may be suppressed.

If the surface resistance R₀ of the polyester film surface is greater than the suitable range described above, there is a tendency that static electricity is generated, and the adhesive force is prone to decrease. On the other hand, if the surface resistance R₀ of the polyester film surface is less than the suitable range, there occurs a need to provide on the polyester surface an electrically conductive layer containing a large amount of a conductive agent such as conductive particles or a conductive resin, and there is a tendency that the durability against heat and humidity is prone to decrease.

<Polyester>

Hereinafter, the polyester that is contained in the polyester film (polymer support) according to the invention will be described more specifically.

The polyester that is contained in the polyester film according to the invention is a linear saturated polyester containing dicarboxylic acid constituent components and diol constituent components.

The polyester is preferably such that the proportion of an aromatic dicarboxylic acid constituent component among the dicarboxylic acid constituent components is from 90% by mole to 100% by mole. If the proportion of the aromatic dicarboxylic acid constituent component is lower than 90% by mole, there are occasions in which moisture and heat resistance, and heat resistance may decrease. When the proportion of the aromatic dicarboxylic acid constituent component among the dicarboxylic acid constituent components of the polyester in the polyester film of the invention is adjusted to the range of from 90% by mole to 100% by mole, a good balance may be achieved between the moisture and heat resistance and the heat resistance.

The proportion of the aromatic dicarboxylic acid constituent component in the polyester is more preferably from 95% by mole to 100% by mole, even more preferably from 98% by mole to 100% by mole, particularly preferably from 99% by mole to 100% by mole, and most preferably 100% by mole. That is, it is most preferable that the entirety of the dicarboxylic acid constituent component is composed of an aromatic carboxylic acid constituent component.

Suitable examples of the main repeating units consisting of the dicarboxylic acid constituent components and the diol constituent components, which mainly constitute the polyester, include ethylene terephthalate, ethylene-2,6-naphthalene dicarboxylate, propylene terephthalate, butylene terephthalate, 1,4-cyclohexylene dimethylene terephthalate, ethylene-2,6-naphthalene dicarboxylate, and mixtures thereof. The term “main repeating units” as used herein mean that the total amount of those repeating units is 70% by mole or greater of the total amount of the repeating units contained in the polyester, and the proportion is more preferably 80% by mole or greater, and even more preferably 90% by mole or greater.

Furthermore, from the viewpoints that polymerization may be carried out at low cost and more easily and the resulting polymer has excellent heat resistance, it is preferable that ethylene terephthalate, ethylene-2,6-naphthalene dicarboxylate, and a mixture thereof constitute the main constituent unit. In this case, when more of ethylene terephthalate is used as a constituent unit, a film having general-purpose usefulness and having moisture and heat resistance may be obtained at lower cost. Furthermore, when more of ethylene-2,6-naphthalene dicarboxylate is used as a constituent unit, a film having superior moisture and heat resistance may be obtained.

As copolymerization components of the polyester, various dicarboxylic acid components or ester-forming derivatives thereof and diol components shown below may be used.

Examples of copolymerizable dicarboxylic acid components include isophthalic acid, phthalic acid, 1,4-naphthalenedicarboxylic acid, 1,5-naphthalenedicarboxylic acid, 2,6-naphthalenedicarboxylic acid, 4,4′-diphenyldicarboxylic acid, 4,4′-diphenyl ether dicarboxylic acid, and 4,4′-diphenylsulfonedicarboxylic acid. Furthermore, examples of copolymerizable alicyclic dicarboxylic acid components include 1,4-cyclohexanedicarboxylic acid.

Furthermore, examples of the diol components include aliphatic, alicyclic and aromatic diols such as ethylene glycol, 1,2-propanediol, neopentyl glycol, 1,3-butanediol, 1,4-butanediol, 1,5-pentanediol, 1,6-hexanediol, 1,2-cyclohexanedimethanol, 1,3-cyclohexanedimethanol, 1,4-cyclohexanedimethanol, diethylene glycol, triethylene glycol, polyalkylene glycol, and 2,2-bis(4′-β-hydroxyethoxyphenyl)propane.

These components may be used singly, or two or more kinds thereof may be used in combination.

The melting point of the polyester which is used with preference in the polyester film according to the invention is preferably 250° C. or higher in view of heat resistance, and is preferably 300° C. or lower in view of productivity. When the melting point is within this range, other components may be copolymerized or blended with the polyester.

Furthermore, various known additives, for example, an oxidation inhibitor, an antistatic agent, a crystallization nucleating agent, inorganic particles, and organic particles may be incorporated into the polyester. Particularly, inorganic particles or organic particles are effective for an enhancement of the handleability of the film by imparting good slipperiness to the film surface.

The polyester may be produced according to a conventionally known method for producing a polyester. That is, the polyester may be produced using a dialkyl ester as an acid component, by subjecting this component and a diol component to a transesterification reaction, and then heating the product of this reaction under reduced pressure to perform polycondensation of the product while removing excess diol component. Furthermore, the polyester may also be produced by a conventionally known direct polymerization method using a dicarboxylic acid as an acid component. Examples of a reaction catalyst that may be used include conventionally known titanium compounds, lithium compounds, calcium compounds, magnesium compounds, antimony compounds and germanium compounds.

In regard to the polyester thus obtained, the degree of polymerization may be further increased, while the terminal carboxyl group concentration may be decreased, by subjecting the polyester to solid state polymerization.

The solid state polymerization is preferably carried out in a dryer at a temperature of 200° C. to 250° C. under reduced pressure of 1 Torr or less or under a nitrogen gas stream for 5 to 50 hours.

One suitable aspect of the polyester according to the invention includes a polyester having a dicarboxylic acid constituent component, a diol constituent component, and a constituent component (p) of which the sum of the number of carboxyl groups (a) and the number of hydroxyl groups (b) (a+b) is 3 or greater, the polyester having a content of the constituent component (p) of from 0.005% by mole to 2.5% by mole relative to the total amount of the constituent components contained in the polyester.

—Constituent Component (p)—

The constituent component (p) of which the sum of the number of carboxyl groups (a) and the number of hydroxyl groups (b) (a+b) is 3 or greater, will be explained.

Examples of the constituent component (p) include a carboxylic acid constituent component having a number of carboxyl groups (a) of 3 or greater, a constituent component having a number of hydroxyl groups (b) of 3 or greater, and a constituent component which is an oxyacid having both hydroxyl groups and carboxyl groups in one molecule, and has a sum of the number of carboxyl groups (a) and the number of hydroxyl groups (b) (a+b) of 3 or greater.

Examples of the carboxylic acid constituent component having a number of carboxyl groups (a) of 3 or greater include, as trifunctional aromatic carboxylic acid constituent components, trimesic acid, trimellitic acid, pyromellitic acid, naphthalenetricarboxylic acid, and anthracenetricarboxylic acid; as trifunctional aliphatic carboxylic acid constituent components, methanetricarboxylic acid, ethanetricarboxylic acid, propanetricarboxylic acid, and butanetricarboxylic acid; as tetrafunctional aromatic carboxylic acid constituent components, benzenetetracarboxylic acid, benzophenonetetracarboxylic acid, naphthalenetetracarboxylic acid, anthracenetetracarboxylic acid, and perylenetetracarboxylic acid; as tetrafunctional aliphatic carboxylic acid constituent components, ethanetetracarboxylic acid, ethylenetetracarboxylic acid, butanetetracarboxylic acid, cyclopentanetetracarboxylic acid, cyclohexanetetracarboxylic acid, and adamantanetetracarboxylic acid; as pentafunctional or higher-functional aromatic carboxylic acid constituent components, benzenepentacarboxylic acid, benzenehexacarboxylic acid, naphthalenepentacarboxylic acid, naphthalenehexacarboxylic acid, naphthaleneheptacarboxylic acid, naphthaleneoctacarboxylic acid anthracenepentacarboxylic acid, anthracenehexacarboxylic acid, anthraceneheptacarboxylic acid, and anthraceneoctacarboxylic acid; as pentafunctional or higher-functional aliphatic carboxylic acid constituent components, ethanepentacarboxylic acid, ethaneheptacarboxylic acid, butanepentacarboxylic acid, butaneheptacarboxylic acid, cyclopentanepentacarboxylic acid, cyclohexanepentacarboxylic acid, cyclohexanehexacarboxylic acid, adamantanepentacarboxylic acid, and adamantanehexacarboxylic acid; and ester derivatives and acid anhydrides thereof. However, the examples are not limited to these.

Furthermore, compounds obtained by adding l-lactide, d-lactide, an oxyacid such as hydroxybenzoic acid, and a derivative thereof, or a plural number of such oxyacids connected in series, to the carboxy terminal of the carboxylic acid constituent component, are also suitably used.

Furthermore, these may be used singly, or if necessary, plural kinds may also be used.

Examples of the constituent component having a number of hydroxyl groups (b) of 3 or greater that may be used with preference include, as trifunctional aromatic constituent components, trihydroxybenzene, trihydroxynaphthalene, trihydroxyanthracene, trihydroxycalchone, trihydroxyflavone, and trihydroxycoumarin; as trifunctional aliphatic alcohol constituent components, glycerin, trimethylolpropane, and propanetriol; as tetrafunctional aliphatic alcohol constituent components, compounds such as pentaerythritol; and constituent components (p) having a diol added to the hydroxy terminal of the compounds described above. These may be used singly, or if necessary, plural kinds may also be used.

Among the oxyacids having both hydroxyl groups and carboxyl groups in one molecule, examples of the constituent component of which the sum of the number of carboxyl groups (a) and the number of hydroxyl groups (b) (a+b) is 3 or greater include hydroxyisophthalic acid, hydroxyterephthalic acid, dihydroxyterephthalic acid, and dihydroxyterephthalic acid.

Furthermore, compounds obtained by adding l-lactide, d-lactide, an oxyacid such as hydroxybenzoic acid, and a derivative thereof, or a plural number of such oxyacids connected in series, to the carboxy terminal of the constituent component, are also suitably used.

Furthermore, these may be used singly, or if necessary, plural kinds may also be used.

In the case where the polyester contains a constituent component (p), the content of the constituent component (p) is preferably from 0.005% by mole to 2.5% by mole relative to the total amount of the constituent components of the polyester. The content of the constituent component (p) is more preferably from 0.020 to 1, even more preferably from 0.025 to 1, still more preferably from 0.035 to 0.5, still more preferably from 0.05 to 0.5, and particularly preferably from 0.1 to 0.25.

When the content of the constituent component (p) in the polyester is 0.005% by mole or less relative to the total amount of the constituent components in the polyester, there are occasions in which the effect of enhancing moisture and heat resistance is not verified. When the content is greater than 2.5% by mole, it is difficult to realize the polyester for the reason such as gelling of the resin and difficulty in melt extrusion, and even if realization of the polymer is possible, the gel is present as a foreign substance, so that there are occasions in which biaxial stretchability is decreased when the polyester is formed into a film, or a film obtained by stretching the polyester has many foreign substance defects.

When the content of the constituent component (p) in the polyester is adjusted to the range of from 0.005% by mole to 2.5% by mole relative to the total amount of the constituent components of the polyester, moisture and heat resistance may be increased while melt extrudability is maintained. Furthermore, the stretchability at the time of biaxial stretching, or the quality of the film thus obtained may be maintained.

The constituent component (p) is preferably such that the compound that has a number of carboxyl groups (a) of 3 or greater and has carboxylic acids, is an aromatic compound, or the compound that has a number of hydroxyl groups (b) of 3 or greater and has hydroxyl groups, is an aliphatic compound. A crosslinked structure may be formed without deteriorating the orientation characteristics of the polyester film, and molecular mobility may be further decreased, while moisture and heat resistance may be further increased.

In the case where the polyester contains the constituent component (p), it is also preferable to add a buffering agent or a terminal blocking agent, which will be described below, at the time of molding.

The polyester containing the constituent component (p) is preferably a highly crystalline resin, and specifically, the polyester is preferably a polyester of which the heat of crystal melting AHm determined from the peak area of the melting peak in a 2^{nd} run differential scanning calorimetric chart, which is obtained according to JIS K7122 (1999) by heating the resin at a temperature increase rate of 20° C./min from 25° C. to 300° C. (1^{st} run), maintaining the resin in that state for 5 minutes, subsequently rapidly cooling the resin to a temperature of 25° C. or lower, and raising the temperature again at a temperature increase rate of 20° C./min from room temperature to 300° C., is 15 J/g or greater. Preferably, it is desirable to use a resin having a heat of crystal melting of 20 J/g or greater, more preferably 25 J/g or greater, and even more preferably 30 J/g or greater. When the polyester is made highly crystalline as such, oriented crystallization may be achieved by stretching and heat treatment, and as a result, a polyester film having excellent mechanical strength and moisture and heat resistance may be obtained.

The melting point Tm of the polyester containing the constituent component (p) is preferably 245° C. to 290° C. The melting point Tm used herein is a melting point Tm obtainable by DSC during a process of temperature increase (temperature increase rate: 20° C./min), and the temperature of a peak top that may be designated as a peak of crystal melting of a 2^{nd} run, which is obtainable by a method based on JIS K-7121 (1999) as described above, by heating the resin at a temperature increase rate of 20° C./min from 25° C. to 300° C. (1^{st} run), maintaining the resin in that state for 5 minutes, subsequently rapidly cooling the resin to a temperature of 25° C. or lower, and raising the temperature again at a temperature increase rate of 20° C./min from room temperature to 300° C., is designated as the melting point Tm1 of the polyester. More preferably, the melting point Tm is 247° C. to 275° C., and even more preferably 250° C. to 265° C. If the melting point Tm is lower than 245° C., the film has inferior heat resistance or the like, which is not preferable. Furthermore, if the melting point Tm is higher than 290° C., it may become difficult to perform extrusion processing, and therefore, it is not preferable. When the melting point Tm of the polyester is adjusted to 245° C. to 290° C., a polyester film which achieves a good balance between heat resistance and processability may be obtained.

<Buffering Agent>

The polyester film according to the invention preferably contains a buffering agent. Incorporation of a buffering agent is particularly preferable when the polyester contains the constituent component (p) as a constituent component thereof.

The buffering agent is preferably an alkali metal salt from the viewpoints of polymerization reactivity and moisture and heat resistance, and specific examples of the buffering agent include alkali metal salts with compounds such as phthalic acid, citric acid, carbonic acid, lactic acid, tartaric acid, phosphoric acid, phosphorous acid, hypophosphorous acid, and polyacrylic acid. Among these, it is preferable that the alkali metal element be potassium or sodium, from the viewpoint that precipitates based on catalyst residues are not easily produced. Specific examples of the buffering agent include potassium hydrogen phthalate, sodium dihydrogen citrate, disodium hydrogen citrate, potassium dihydrogen citrate, dipotassium hydrogen citrate, sodium carbonate, sodium tartrate, potassium tartrate, sodium lactate, potassium lactate, sodium hydrogen carbonate, disodium hydrogen phosphate, dipotassium hydrogen phosphate, potassium dihydrogen phosphate, sodium dihydrogen phosphate, sodium hydrogen phosphite, potassium hydrogen phosphite, sodium hypophosphite, potassium hypophosphite, and sodium polyacrylate.

Furthermore, the buffering agent is preferably an alkali metal salt represented by the following formula (I), from the viewpoints of the polymerization reactivity of the polyester, and heat resistance at the time of melt molding. Furthermore, an alkali metal is preferably sodium and/or potassium, from the viewpoints of polymerization reactivity, heat resistance, and moisture and heat resistance, and is particularly preferably a metal salt of phosphoric acid and sodium and/or potassium, from the viewpoints of polymerization reactivity and moisture and heat resistance.

POₓH_{y}M_{z} (I)

wherein x represents an integer from 2 to 4; y represents 1 or 2; z represents 11 or 2; and M is an alkali metal).

The content of the buffering agent is preferably from 0.1 mol/ton to 5.0 mol/ton, relative to the total mass of the polyester, and is more preferably from 0.3 mol/ton to 3.0 mol/ton. When the content of the buffering agent is in the range described above, moisture and heat resistance or mechanical characteristics may be further enhanced.

In the case of using an alkali metal salt represented by the formula (I) as the buffering agent, it is preferable to use phosphoric acid together. Thereby, the effect of suppressing hydrolysis by the buffering agent may be further increased, and the moisture and heat resistance of the polyester film thus obtainable may be further increased.

In that case, it is preferable to adjust the alkali metal element content W1 in the polyester film to the range of from 2.5 ppm to 125 ppm, and to adjust the ratio of the alkali metal element content W1 and the phosphorus element content W2, W1/W2, to the range of from 0.01 to 1. When the contents are adjusted to these ranges, the effect of suppressing hydrolysis may be further enhanced. More preferably, the alkali metal element W1 is from 15 ppm to 75 ppm, and the ratio of the alkali metal element content W1 and the phosphorus element content W2, W1/W2, is from 0.1 to 0.5. If the alkali metal element content W1 is less than 2.5 ppm, the effect of suppressing hydrolysis is insufficient, and the resulting polyester film may not obtain sufficient moisture and heat resistance. Furthermore, if the alkali metal element content is greater than 125 ppm, the alkali metal which is present in excess may accelerate a thermal decomposition reaction at the time of melt extrusion, and the molecular weight may decrease, thereby causing a decrease in moisture and heat resistance or in the mechanical properties. Furthermore, when the ratio of the alkali metal element content W1 and the phosphorus element content W2, W1/W2, is less than 0.1, the effect of suppressing hydrolysis is insufficient. When the ratio is greater than 125 ppm, the excess phosphoric acid reacts with the polyester during the polymerization reaction to form a phosphoric acid ester skeleton into a molecular chain, and this part accelerates the hydrolysis reaction, so that hydrolysis resistance may decrease.

When the alkali metal element W1 in the polyester film is from 15 ppm to 75 ppm, and the ratio of the alkali metal element contents W1 and W2, W1/W2, is from 0.1 to 0.5, the effect of suppressing hydrolysis resistance may be further increased, and as a result, high moisture and heat resistance may be obtained.

The buffering agent may be added during the polymerization of polyester, or may be added at the time of melt molding, but from the viewpoint of uniform dispersion of the buffering agent in the film, it is preferable to add the buffering agent during the polymerization. When the buffering agent is added during the polymerization, the timing of addition is such that the buffering agent may be added at any time between the completion of the esterification reaction or transesterification reaction during the polymerization of the polyester, and the early stage of the polycondensation reaction (when the intrinsic viscosity is less than 0.3). The method for addition of the buffering agent may be any of a method of directly adding a powder, and a method of preparing a solution in which the buffering agent is dissolved in a diol constituent component such as ethylene glycol and adding the solution; however, it is preferable to add the buffering agent as a solution in which the buffering agent is dissolved in a diol constituent component such as ethylene glycol. In that case, in regard to the solution concentration, if the solution is diluted to 10% by mass or less and added, it is preferable from the viewpoints that there occurs less adhesion of the buffering agent to the vicinity of the addition port, the error in the amount of addition is small, and the reactivity is satisfactory.

Furthermore, in the case of a polyester containing the constituent component (p), it is preferable that the content of diethylene glycol, which is a side product produced during the polymerization, be less than 2.0% by mass, and more preferably less than 1.0% by mass, from the viewpoints of heat resistance and moisture and heat resistance.

<Terminal Blocking Agent>

According to one preferred aspect, the polyester film according to the invention contains a terminal blocking agent. The terminal blocking agent is an additive that reacts with the terminal carboxyl group of the polyester and thereby reducing the amount of carboxyl terminals of the polyester.

Examples of the terminal blocking agent include carbodiimide compounds, epoxy compounds, and oxazoline compounds.

The terminal blocking agent is more effective when added together with the polyester during the formation of a polyester film. It is also acceptable to use the terminal blocking agent simultaneously at the time of solid state polymerization.

The terminal blocking agent may also be used together with the polyester containing the constituent component (p) of which the sum of the number of carboxyl groups (a) and the number of hydroxyl groups (b) (a+b) is 3 or greater.

The content of the terminal blocking agent in the polyester film is preferably 0.1% by mass to 5% by mass. If the content of the terminal blocking agent is less than 0.1% by mass, the effect of blocking the carboxyl group is small, and the hydrolysis resistance may be deteriorated. Furthermore, if the content of the terminal blocking agent is larger than 5% by mass, foreign materials may be produced to a large extent during film formation, a decomposition gas may be generated, or the productivity may be affected. A more preferred upper limit of the content of the terminal blocking agent is 4% by mass, and an even more preferred upper limit thereof is 2% by mass. A more preferred lower limit of the content of the terminal blocking agent is 0.3% by mass, and an even more preferred lower limit thereof is 0.5% by mass. A more preferred range of the content of the terminal blocking agent is 0.3% by weight to 4% by weight, and an even more preferred range is 0.5% by weight to 2% by weight.

Carbodiimide Compound—

The carbodiimide compounds are classified into monofunctional carbodiimides and polyfunctional carbodiimides.

Examples of the monofunctional carbodiimides include dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, and di-β-naphthylcarbodiimide. Particularly preferred examples include dicyclohexylcarbodiimide and diisopropylcarbodiimide.

Furthermore, carbodiimides having a degree of polymerization of 3 to 15 are used with preference as the polyfunctional carbodiimides. Specific examples include 1,5-naphthalenecarbodiimide, 4,4′-diphenylmethanecarbodiimide, 4,4′-diphenyldimethylmethanecarbodiimide, 1,3-phenylenecarbodiimide, 1,4-phenylene diisocyanate, 2,4-tolylenecarbodiimide, 2,6-tolylenecarbodiimide, a mixture of 2,4-tolylenecarbodiimide and 2,6-tolylenecarbodiimide, hexamethylenecarbodiimide, cyclohexane-1,4-carbodiimide, xylylenecarbodiimide, isophoronecarbodiimide, isophoronecarbodiimide, dicyclohexylmethane-4,4′-carbodiimide, methylcyclohexanecarbodiimide, tetramethylxylylenecarbodiimide, 2,6-diisopropylphenylcarbodiimide, and 1,3,5-triisopropylbenzene-2,4-carbodiimide.

These may be used singly or in combination of two or more kinds thereof.

Since the carbodiimide compounds generate isocyanate-based gases as a result of thermal decomposition, carbodiimide compounds having high heat resistance are preferred. In order to increase heat resistance, carbodiimide compounds having a higher molecular weight (degree of polymerization) are preferred, and it is more preferable to impart a structure having high heat resistance to the terminals of the carbodiimide compound. Furthermore, if a carbodiimide compound once undergoes thermal decomposition, the carbodiimide compound is prone to undergo another thermal decomposition. Therefore, it is needed to devise a process in a way such as lowering the extrusion temperature of the polyester as much as possible.

—Epoxy Compounds—

Preferred examples of the epoxy compounds include glycidyl ester compounds and glycidyl ether compounds.

Specific examples of the glycidyl ester compounds include benzoic acid glycidyl ester, t-Bu-benzoic acid glycidyl ester, P-toluic acid glycidyl ester, cyclohexanecarboxylic acid glycidyl ester, pelargonic acid glycidyl ester, stearic acid glycidyl ester, lauric acid glycidyl ester, palmitic acid glycidyl ester, behenic acid glycidyl ester, versatic acid glycidyl ester, oleic acid glycidyl ester, linolic acid glycidyl ester, linoleic acid glycidyl ester, behenolic acid glycidyl ester, stearolic acid glycidyl ester, terephthalic acid diglycidyl ester, isophthalic acid diglycidyl ester, phthalic acid diglycidyl ester, naphthalenedicarboxylic acid diglycidyl ester, methylterephthalic acid diglycidyl ester, hexahydrophthalic acid diglycidyl ester, tetrahydrophthalic acid diglycidyl ester, cyclohexanedicarboxylic acid diglycidyl ester, adipic acid diglycidyl ester, succinic acid diglycidyl ester, sebacic acid diglycidyl ester, dodecanedioic acid diglycidyl ester, octadecanedicarboxylic acid diglycidyl ester, trimellitic acid triglycidyl ester, and pyromellitic acid tetraglycidyl ester. These may be used singly or in combination of two or more kinds thereof.

Specific examples of the glycidyl ether compounds include phenyl glycidyl ether, O-phenyl glycidyl ether, 1,4-bis(β,γ-epoxypropoxy)butane, 1,6-bis(β,γ-epoxypropoxy)hexane, 1,4-bis(β,γ-epoxypropoxy)benzene, 1-(β,γ-epoxypropoxy)-2-ethoxyethane, 1-(β,γ-epoxypropoxy)-2-benzyloxyethane, 2,2-bis[p-(β,γ-epoxypropoxy)phenyl]propane, 2,2-bis(4-hydroxyphenyl)propane, and a bisglycidyl polyether which is obtainable by a reaction between bisphenol such as 2,2-bis(4-hydroxyphenyl)methane and epichlorohydrin. These may be used singly or in combination of two or more kinds thereof.

—Oxazoline Compounds—

The oxazoline compounds are preferably bisoxazoline compounds, and specific examples include 2,2′-bis(2-oxazoline), 2,2′-bis(4-methyl-2-oxazoline), 2,2′-bis(4,4-dimethyl-2-oxazoline), 2,2′-bis(4-ethyl-2-oxazoline), 2,2′-bis(4,4′-diethyl-2-oxazoline), 2,2′-bis(4-propyl-2-oxazoline), 2,2′-bis(4-butyl-2-oxazoline), 2,2′-bis(4-hexyl-2-oxazoline), 2,2′-bis(4-phenyl-2-oxazoline), 2,2′-bis(4-cyclohexyl-2-oxazoline), 2,2′-bis(4-benzyl-2-oxazoline), 2,2′-p-phenylenebis(2-oxazoline), 2,2′-m-phenylenebis(2-oxazoline), 2,2′-o-phenylenebis(2-oxazoline), 2,2′-p-phenylenebis(4-methyl-2-oxazoline), 2,2′-p-phenylenebis(4,4-dimethyl-2-oxazoline), 2,2′-m-phenylenebis(4-methyl-2-oxazoline), 2,2′-m-phenylenebis(4,4-dimethyl-2-oxazoline), 2,2′-ethylenebis(2-oxazoline), 2,2′-tetramethylenebis(2-oxazoline), 2,2′-hexamethylenebis(2-oxazoline), 2,2′-octamethylenebis(2-oxazoline), 2,2′-decamethylenebis(2-oxazoline), 2,2′-ethylenebis(4-methyl-2-oxazoline), 2,2′-tetarmethylenebis(4,4-dimethyl-2-oxazoline), 2,2′-9,9′-diphenoxyethanebis(2-oxazoline), 2,2′-cyclohexylenebis(2-oxazoline) and 2,2′-diphenylenebis(2-oxazoline). Among these, 2,2′-bis(2-oxazoline) is most preferably used from the viewpoint of the reactivity with the polyester.

The bisoxazoline compounds may be used singly alone, or two or more kinds may be used together.

<Phosphorus Compound>

For the polyester film according to the invention, it is also preferable to incorporate a phosphorus compound from the viewpoint of suppressing the decomposition of hydrolysis.

In the case of incorporating a phosphorus compound, it is preferable that the amount of phosphorus atoms determined by a fluorescent X-ray analysis of the polyester film be 200 ppm or greater. The amount of phosphorus atoms is more preferably 300 ppm or greater, and even more preferably 400 ppm or greater.

As the phosphorus compound, it is preferable to use one or more phosphorus compounds selected from the group consisting of phosphoric acid, phosphorous acid, phosphonic acid, and methyl esters, ethyl esters, phenyl esters, and half esters of those acids, and other derivatives thereof. According to the invention, methyl esters, ethyl ester and phenyl esters of phosphoric acid, phosphorous acid and phosphonic acid are particularly preferred. Furthermore, as a method of incorporating the phosphorus compound, it is preferable to add the phosphorus compound when polyester raw material chips are produced.

<Other Additives>

Since the polyester film according to the invention is a constituent element of a back sheet for solar cells, it is preferable that the polyester film is not easily affected by deterioration due to sunlight. For that reason, a UV (ultraviolet) absorber or a substance having a characteristic of reflecting UV may be added into the film. Furthermore, according to one preferred aspect, the average reflective ratio for a radiation having a wavelength of 400 to 700 nm at least one surface of the film is adjusted to 80% or greater. The average reflective ratio is more preferably 85% or greater, and particularly preferably 90% or greater. When the average reflective ratio of a radiation having a wavelength of 400 to 700 nm is adjusted to 80% or greater, even if a solar cell using the film of the invention is used at places which are directly exposed to sunlight, deterioration of the film occurs to a lesser extent.

(Method for Producing Polyester Film)

Next, the method for producing the polyester film according to the invention will be explained by way of an example of a biaxially oriented polyester film which uses polyethylene terephthalate (PET) as the polyester, as a representative example.

Of course, the invention is not intended to be limited to the biaxially oriented polyester film which uses a PET film, and films which use any other polymers are also acceptable. For example, when a polyester film is constructed using polyethylene-2,6-naphthalenedicarboxylate, which has a high glass transition temperature or a high melting point, extrusion or stretching may be carried out at higher temperatures than the temperatures shown below.

<Film Formation/Extrusion>

The polyester film according to the invention is produced, for example, as follows.

First, a raw (unstretched) polyester sheet that constitutes the polyester film is produced. In order to produce a raw polyester sheet, for example, pellets of the polyester prepared as described above are melted using an extruder, and the molten product is ejected through a nozzle (die) and then is molded into a sheet form through cooling and solidification. At this time, it is preferable to filter the polymer through a fiber-sintered stainless steel metal filter so as to remove unmelted matter in the polymer.

Furthermore, it is also another preferred aspect to add inorganic particles or organic particles, for example, inorganic particles of clay, mica, titanium oxide, calcium carbonate, kaolin, talc, wet silica, dry silica, colloidal silica, calcium phosphate, barium sulfate, alumina, zirconia and the like; organic particles constituted of acrylic acids, styrene-based resins, thermosetting resins, silicones, imide-based compounds and the like; and particles that are precipitated due to the catalyst and the like added during the polymerization reaction of the polyester (so-called internal particles), in order to impart good slipperiness, abrasion resistance, scratch resistance and the like to the surface of the polyester film.

Furthermore, as long as the effects of the invention are not impaired, various additives, for example, a compatibilizing agent, a plasticizer, a weather resistant agent, an oxidation inhibitor, a thermal stabilizer, a gliding agent, an antistatic agent, a brightening agent, a colorant, an electroconductive agent, an ultraviolet absorber, a flame retardant, a flame retardant aid, a pigment and a dye, may also be added.

When such an additive or a terminal blocking agent is incorporated into the polyester, a method of mixing the terminal blocking agent directly with PET pellets, kneading the mixture using a vent type twin-screw kneading extruder which has been heated to a temperature of 270° C. to 275° C., and forming the kneading product into a high concentration master pellet, is effective.

Subsequently, the pellets of PET thus obtained are dried under reduced pressure for 3 or more hours at a temperature of 180° C., and then the dried pellets are supplied to an extruder which has been heated to a temperature of 265° C. to 280° C., more preferably to a temperature of 270° C. to 275° C., under a nitrogen gas stream or under reduced pressure so as to prevent the intrinsic viscosity from decreasing. The pellets are extruded through a slit die and cooled on a casting roll, and thus an unstretched film is obtained. In this case, it is preferable to use various filters, for example, filters made of materials such as sintered metals, porous ceramics, sand and iron wire, in order to remove foreign materials or degenerate polymer. Furthermore, a gear pump may also be provided if necessary, in order to improve metered supply. In the case of laminating a film, plural different polymers are melt laminated using two or more extruders and a manifold or a joint block. Melt lamination is used preferably when, for example, the reflective layer (white layer) is co-extruded.

The molten body (melt) extruded from an extruder as such is solidified on a casting (cooling) roll to which a temperature distribution has been imparted as described above, and thus a raw film (unstretched film) is obtained. A preferred temperature of the cooling roll is preferably from 10° C. to 60° C., more preferably from 15° C. to 55° C., and even more preferably from 20° C. to 50° C. At this time, in order to enhance the adhesive force between the melt and the cooling roll, an electrostatic application method, an air knife method, a method of forming a water film on the cooling roll, and the like may be used with preference.

Furthermore, according to the invention, when the melt is extruded onto a cast roll, it is preferable to set the linear velocity of the cast roll to 10 m/min or greater, more preferably from 15 m/min to 50 m/min, and even more preferably from 18 m/min to 40 m/min. If the linear velocity is equal to or less than this range, the retention time of the melt on the cast roll is lengthened, and especially, the temperature difference given by this method becomes even, so that the effects are reduced. On the other hand, if the linear velocity is greater than this range, thickness irregularity of the melt is prone to occur, and the temperature unevenness of the melt caused by the thickness irregularity exceeds the range described above, which is not preferable. In order to achieve such a velocity of the cast roll, it is necessary to set the kneading speed in the extruder to a high level, and in conventional methods, the AV is prone to increase due to the shear heat generation of the resin along with an increase in the speed of rotation of the screw. Such a phenomenon is prone to be manifested particularly conspicuously in the present invention which uses a resin having a high IV. For this reason, the invention is characterized by adding fine particles of a resin to the extruder. That is, the time point at which shear heat generation is most likely to occur is the initiation of melting during the early stage of kneading, and in this stage, pellets and the screw strongly rub against each other and generate heat. By adding fine particles of a resin at this stage, the friction between the pellets is reduced, and an increase in the AV is suppressed, so that the AV may be adjusted to the range of the invention. The size of these fine particles is preferably set to the range of from 200 meshes to 10 meshes, and the fine particles are obtained by crushing the pellets and sieving the crushed product. The amount of addition of these fine particles is preferably from 0.1% to 5%, more preferably from 0.3% to 4%, and even more preferably from 0.5% to 3%. When the amount of addition is less than this range, the effects described above are insufficient, and when the amount of addition is greater than this range, abrasion with the screw becomes too strong, and slippage occurs. Furthermore, pressure unevenness of the melt occurs due to a fluctuation in ejection, and the temperature distribution on the cast roll exceeds the range of the invention, which is not preferable.

<Film Formation/Longitudinal Stretching>

Subsequently, the raw film (unstretched film) is obtained above, is biaxially stretched in the longitudinal direction and the lateral direction and then heat treated. The method of performing biaxial stretching may be any of a sequential biaxial stretching method of performing stretching in the longitudinal direction and the width direction separately, as described above, and a simultaneous biaxial stretching method of performing stretching in the longitudinal direction and the width direction at the same time.

The biaxially stretching is described. The unstretched film is stretched in the longitudinal direction by a longitudinal stretching machine with several rolls by using the difference of circumferential velocity of rolls (MD stretching) and then stretched in the lateral direction by a tentor (TD stretching).

It is preferable to preheat sufficiently the unstretched film before MD stretching. A temperature of the preliminary heating is preferably from 40° C. to 90° C., more preferably from 50° C. to 85° C. and even more preferably from 60° C. to 80° C. The preheat is conducted by passing the raw film on a heat (temperature control) roll to which a temperature distribution in the lateral direction has been imparted as described above. A time of the preliminary heating is preferably from 1 second to 120 seconds, more preferably from 5 seconds to 60 seconds, more preferably 10 seconds to 40 seconds. MD stretching can be carried out by a single stage or a multistage.

In the single stage, the temperature of the MD stretching is from a glass-trasition temperature (Tg) to Tg+15° C. (more preferably to Tg+10° C.). The stretch ratio is preferably set to from 2.0 times to 6.0 times, more preferably from 3.0 times to 5.5 times, even more preferably from 3.5 times to 5.0 times. It is preferable to be cooled with a group of rolls at a temperature of from 20° C. to 50° C. after stretching.

Since the polyester film according to the present invention has a large IV and the higher molecular weight, a molecular mobility is decreased and oriented crystallization may not be achieved. Therefore, it is preferable to carry out the multistage stretching. First, stretching is carried out in a low temperature and thereafter a second stretching is carried out in a higher temperature. The oriented crystallization is achieved to obtain a high orientation. The first low temperature stretching (MD1 stretching) is carried out by heated with a group of heating rolls in a range from (Tg−20° C.) to (Tg+10° C.), more preferably from (Tg−10° C.) to (Tg+5° C.). The polyester film is stretched at a stretching ratio of preferably from 1.1 times to 3.0 times in the longitudinal direction, more preferably from 1.2 times to 2.5 times, even more preferably from 1.5 times to 2.0 times and then MD2 stretching is carried out in a range from (Tg+10° C.) to (Tg+50° C.) which is higher than MD1 stretching temperature. Preferable temperature is from (Tg+10° C.) to (Tg+50° C.) and preferable MD2 stretching ratio is preferably from 1.2 times to 4.0 times, more preferably from 1.5 times to 3.0 times. A total MD stretching ratio combined MD1 stretching and MD2 stretching is preferably from 2.0 times to 6.0 times, more preferably from 3.0 times to 5.5 times, even more preferably from 3.5 times to 5.0 times. The ratio of stretching ratio of the first stage and the second stage (refereed to a multistage ratio=the second stage/the first stage) is preferably from 1.1 times to 3 times, more preferably from 1.15 times to 2 times, even more preferably from 1.2 times to 1.8 times.

It is preferable to be cooled with a group of rolls at a temperature of from 20° C. to 50° C. after stretching.

<Film Formation/Lateral Stretching>

Subsequently, the film is stretched in the width direction by using a tenter (also referred to as a stentor) at a stretch ratio of from 2.0 times to 6.0 times, preferably from 3.0 times to 5.5 times, more preferably from 3.5 times to 5.0 times. A range of temperature of stretching is (Tg) to (Tg+50° C.) and preferably from (Tg) to (Tg+30° C.) (TD stretching).

<Heat Treatment>

A heat treatment is carried out after stretching. The heat treatment can be carried out in a tentor or a heating oven or on a heated roll by any known methods. Though the heat treatment is generally carried out at the melting temperature of polyester or less, it is preferable to be carried out in the above described temperature and time, wherein relaxation in at least one of the longitudinal direction or the lateral direction is preferable as the above described to obtain thermal shrinkage of the film of the present invention.

Subsequently, the heat treated film is rolled up to obtain the polyester film of the present invention.

<Evaluation Methods>

The evaluation methods for the characteristics that are applied to the present specification, including the Examples of the invention that will be described below, will be shown below.

(1) Intrinsic Viscosity

A film is dissolved in ortho-chlorophenol, and the solution viscosity is measured at 25° C. Thus, the intrinsic viscosity is obtained from the solution viscosity based on the following formula:

ηsp/C=[η]+K[η]2·C

Wherein ηsp=(solution viscosity/solvent viscosity)−1; C represents the dissolved polymer mass dissolved per 100 ml of the solvent (in the present measurement, set to 1 g/100 ml); K represents the Huggins constant (set to 0.343); and the solution viscosity and the solvent viscosity are measured using an Ostwald viscometer.

(2) Terminal Carboxyl Group Concentration

0.5 g of a polyester film is dissolved in o-cresol, and the potential difference is measured by potentiometric titration using potassium hydroxide. Thus, the terminal carboxyl group concentration is determined.

(3) Minor Endothermic Peak Temperature Tmeta (° C.) Determined by Differential Scanning Calorimetry (DSC)

The minor endothermic peak temperature Tmeta (° C.) is measured using a differential scanning calorimetric apparatus (trade name: “ROBOT DSC-RDC220”, manufactured by Seiko Instruments and Electronics Co., Ltd.) according to JIS K7122-1987 (see the JIS Handbook, 1999 edition), and the data analysis is made using “DISK SESSION SSC/5200”. Specifically, 5 mg of a film is weighed on a sample pan, and the measurement is made by increasing the temperature at a temperature increase rate of 20° C./min from 25° C. to 300° C.

A minor endothermic peak temperature appearing before the crystal melting peak in the differential scanning calorimetric chart thus obtained is designated as Tmeta (° C.). When it is difficult to observe a minor endothermic peak, the vicinity of the peak is magnified at the data analysis unit, and the peak is read out.

In addition, the method for reading the graph of a minor endothermic peak is not described in the JIS standards; however, graph reading is carried out based on the following method.

First, a straight line is drawn between the value at 135° C. and the value at 155° C., and the area of the endotherm-side region made between the straight line and the curve of the graph is determined. Similarly, the same areas are determined at 17 points of temperature pairs such as 140° C. and 160° C., 145° C. and 165° C., 150° C. and 170° C., 155° C. and 175° C., 160° C. and 180° C., 165° C. and 185° C., 170° C. and 190° C., 175° C. and 195° C., 180° C. and 200° C., 185° C. and 205° C., 190° C. and 210° C., 195° C. and 215° C., 200° C. and 220° C., 205° C. and 225° C., 210° C. and 230° C., 215° C. and 235° C., and 220° C. and 240° C. Since the amount of heat absorption of the minor peak is normally 0.2 to 5.0 J/g, only the data associated with an area of from 0.2 J/g to 5.0 J/g are handled as effective data. Among the 18 area data in total, the peak temperature of an endothermic peak that is in the temperature region of data which are effective data and show the largest areas, is designated as Tmeta (° C.). If there are no effective data, it is determined that the Tmeta (° C.) is absent.

(4) Thermal Shrinkage Ratio

A sample having a width of 10 mm and a distance between markers of about 100 mm is heat treated according to JIS-C2318 (2007), at a temperature of 150° C. and under a load of 0.5 g for 30 minutes. The distance between markers is measured before and after the heat treatment, using a thermal shrinkage ratio measuring machine (No. AMM-1 machine, manufactured by Techno Needs Co., Ltd.), and the thermal shrinkage ratio is calculated by the following formula:

Thermal shrinkage ratio (%)={(L₀−L)/L₀}×100

L₀: Distance between markers before heating treatment

L: Distance between markers after heating treatment

(5) Plane Orientation Coefficient

The film refractive index is measured using an Abbe refractometer (trade name: TYPE 4T, manufactured by Atago Co., Ltd.) and using a sodium lamp as a light source.

Plane orientation coefficient=(nMD+nTD)/2−nZD (A)

In the formula (A), nMD represents the refractive index in the longitudinal direction (MD) of the film; nTD represents the refractive index in the orthogonal direction (TD) of the film; and nZD represents the refractive index in the thickness direction of the film.

(6) Content of Phosphorus Atoms in Fluorescent X-Ray Analysis

The content of phosphorus atoms is measured by a fluorescent X-ray method (trade name: ZSX100e, manufactured by Rigaku Corp.).

(7) Analysis of Composition of Polyester

A polyester is hydrolyzed using an alkali, the respective components are analyzed by gas chromatography or high performance liquid chromatography, and the composition ratios of the respective components are determined from the peak areas.

An example will be described in the following.

A dicarboxylic acid constituent component or a constituent component having carboxyl groups is measured by high performance liquid chromatography. The analysis may be carried out under known measurement conditions by a known method. The measurement conditions that are applied to the invention will be shown below.

Apparatus: SHIMADZU LC-10A

Column: YMC-PACK ODS-A 150×4.6 mm S-5 μm 120 A

Column temperature: 40° C.

Flow rate: 1.2 ml/min

Detector: UV 240 nm

Quantification of a diol constituent component or a constituent component having hydroxyl groups may be analyzed by a known method using gas chromatography. The measurement conditions that are applied to the invention will be shown below.

Apparatus: SHIMADZU 9A (trade name, manufactured by Shimadzu Corp.)

Column: SUPELCOWAX-10 capillary column 30 m

Column temperature: 140° C. to 250° C. (temperature increase rate 5° C./min)

Flow rate: nitrogen 25 ml/min

Detector: FID

(8) Elongation Retention Ratio after Storage for 72 Hours Under Conditions of 125° C. and Moisture of 100%

Measurement of the breaking elongation is carried out according to ASTM-D882-97 (see ANNUAL BOOK OF ASTM STANDARDS, 1999 edition). A sample is cut to a size of 1 cm×20 cm, and the breaking elongation (initial) is measured by pulling the sample under the conditions of a distance between chucks of 5 cm, and a tensile speed of 300 mm/min. The measurement is made for five samples, and the average value is designated as breaking elongation (initial) A2.

Subsequently, a sample is cut to a size of 1 cm×20 cm, and the sample is treated for 72 hours under the conditions of 125° C. and a moisture of 100%, using a highly accelerated life testing apparatus (HAST apparatus) (trade name: PC-304R8D, manufactured by Hirayama Manufacturing Corp.). Subsequently, the breaking elongation of the sample after the treatment is measured according to ASTM-D882 (1999)-97 (see ANNUAL BOOK OF ASTM STANDARDS, 1999 edition), as a breaking elongation (post-treatment) by pulling the sample under the conditions of a distance between chucks of 5 cm, and a tensile speed of 300 mm/min. The measurement is made for five samples, and the average value is designated as breaking elongation (post-treatment) A3.

The elongations at break A2 and A3 thus obtained are used to calculate the elongation retention ratio by the following formula (3).

Elongation retention ratio (%)=A3/A2×100 (3)

Furthermore, the average elongation retention ratio is calculated by the following formula (4).

Average elongation retention ratio (%)=(Elongation retention ratio in the MD direction+elongation retention ratio in the TD direction)/2 (4)

(9) Specific Surface Resistance (R₀)

The specific surface resistance R₀ of a polyester film is measured using a digital ultra-high resistance microcurrent meter (trade name: R8340, manufactured by Advantest Corp.). However, when the specific surface resistance is 10⁵Ω/□ or less, a LORESTA EP (trade name, manufactured by Dia Instruments Co., Ltd.) equipped with an ASP probe is used. Furthermore, measurement is made at any 10 sites within the film surface, and their average value is designated as the specific surface resistance R₀. A measurement sample which has been left to stand overnight in a room at 23° C. and 65% RH is used to make the measurement.

(Surface Treatment)

The polymer support of the invention is preferably such that the surface provided with an undercoat layer is surface treated. Examples of the surface treatment include a corona discharge treatment, a flame treatment, an ultraviolet treatment, a low pressure plasma treatment, and an atmospheric plasma treatment.

—Corona Discharge Treatment—

In the corona discharge treatment, usually, high frequency, high voltage electricity is applied between a metal roll coated with a dielectric substance (dielectric roll) and insulated electrodes to cause dielectric breakdown of the air present between the electrodes, and thereby the air present between the electrodes is ionized. Thus, a corona discharge is generated between the electrodes. A treatment is performed by passing an object to be treated, through this corona discharge.

For example, conditions such as a gap clearance between the electrodes and the dielectric roll of 1 to 3 mm, a frequency of 1 to 100 kHz, and an applied energy of about 0.2 to 5 kV·A·min/m² are preferred.

—Flame Treatment—

The flame treatment of the invention is a treatment method of bringing the outer flame portion of a flame into contact with a support. Usually, the treatment is carried out by forming a flame with a burner, and hitting this flame on the support surface.

The burner for surface treatment used in the invention is not limited as long as the flame may be made to uniformly hit the support surface. However, the burner may be such that a plural number of circular-shaped burners are disposed so as to maintain uniformity in the width direction, or may be a horizontal slit box type burner having a width equal to or greater than the width of the support. Furthermore, in the case of treating a web-like support, a plural number of this circular-shaped or horizontal slit box type burner may be disposed in the carrier direction of the web.

The flame treatment of the invention may be carried out on a back roll, or may be carried out in a roll-free state between two rolls. However, it is preferable to carry out the flame treatment on a back roll.

In the case of performing the treatment on a back roll, the back roll is preferably a cooling back roll. The temperature of the cooling roll is preferably controlled to be between 10° C. and 100° C., and more preferably between 25° C. and 60° C. If the temperature of the cooling roll is lower than 10° C., condensation may occur. If the temperature is higher than 100° C., the support may undergo deformation.

In regard to the material of the back roll that is used for the flame treatment of the invention, any material may be used as long as it is a heat resistant material, but a metallic material or a ceramic material is appropriate. Examples of the metallic material that may be used include iron, chrome-plated iron, SUS304, SUS316 and SUS420, and other examples include ceramic materials such as alumina, zirconia and silica.

Examples of the combustion gas that is used for the flame treatment of the invention include paraffin-based gases such as town gas, natural gas, methane gas, ethane gas, propane gas and butane gas; and olefin-based gases such as ethylene gas, propylene gas, and acetylene gas. These gases may be used singly, or as mixtures of two or more kinds

According to the invention, oxygen or air is preferably used as an oxidizing gas that is mixed with the combustion gas used in the flame treatment, but a combustion improver or an oxidizing agent may be used.

In regard to the flame treatment, a method of adding silane compounds such as those described in Japanese Patent No. 3893394 and Japanese Patent Application Laid-Open No. 2007-39508 is preferred.

The mixing ratio of the combustion gas and the oxidizing gas for the flame treatment may vary with the type of the gases, but for example, in the case of propane gas and air, a preferred mixing ratio of propane gas/air is, as a volume ratio, preferably in the range of 1/15 to 1/22, and more preferably 1/16 to 1/19, and in the case of natural gas and air, the mixing ratio is preferably ⅙ to 1/10, and more preferably 1/7 to 1/9.

The web according to the invention may be treated at one surface only, or may be treated at both surfaces.

According to the invention, the time for hitting the web with flame, that is, the time for the web to pass through an effective flame portion, is preferably from 0.001 seconds to 2 seconds, and more preferably from 0.01 seconds to 1 second. When a time of 2 seconds or longer is taken, the surface of the web is damaged, and the adhesion ability is lost. Furthermore, when a time of shorter than 0.001 seconds is taken, an oxidation reaction does not easily occur, and it is difficult for the treated surface to contribute to adhesion.

—Ultraviolet Treatment—

The ultraviolet treatment is a treatment of irradiating a sample surface with ultraviolet radiation and thereby improving adhesiveness, wettability, print suitability and the like.

A “low pressure mercury lamp (low pressure mercury UV lamp)” is usually used as an ultraviolet radiation generating source. An effect of surface treatment may be obtained by ultraviolet radiations at 254 nm and 185 nm from a low pressure mercury lamp, and particularly by the latter.

The ultraviolet treatment is usually carried out for 1 to 500 seconds under atmospheric pressure. If the treatment time is 1 second or less, the effect of improving adhesiveness may be insufficient. On the contrary, if the treatment time exceeds 500 seconds, there may be problems with coloration of the support and the like.

—Low Pressure Plasma Treatment—

The low pressure plasma treatment of the invention will be described.

Low pressure plasma is a method of generating plasma as a result of discharge in a gas (plasma gas) in a low pressure atmosphere and thereby treating a support surface.

Examples of the plasma gas that may be used include inorganic gases such as oxygen gas, nitrogen gas, water vapor gas, argon gas and helium gas, and particularly, oxygen gas, or a mixed gas of oxygen gas and argon gas is preferred. Specifically, it is preferable to use a mixed gas of oxygen gas and argon gas. In the case of using oxygen gas and argon gas, the ratio of the two gases is preferably such that the partial pressure ratio of oxygen gas:argon gas is about 100:0 to 30:70, and more preferably about 90:10 to 70:30.

The pressure of the plasma gas is preferably in the range of about 0.005 to 10 Torr, and more preferably 0.008 to 3 Torr. If the pressure of the plasma gas is less than 0.005 Torr, the effect of improving adhesiveness may be insufficient. On the contrary, if the pressure exceeds 10 Torr, the current increases, and a discharge may be unstably achieved.

Furthermore, the plasma output power is preferably about 100 to 2500 W, and more preferably about 500 to 1500 W.

The treatment time is preferably 0.05 to 100 seconds, and more preferably about 0.5 to 30 seconds. If the treatment time is shorter than 0.05 seconds, the effect of improving adhesiveness may be insufficient. On the other hand, if the treatment time is longer than 100 seconds, there may be problems such as deformation of the support and coloration.

In regard to the plasma treatment of the invention, a method of generating plasma may be carried out using an apparatus for a direct current glow discharge, a high frequency wave discharge, a microwave discharge or the like. Particularly, a method of carrying out the plasma treatment utilizing a discharge device which uses a high frequency wave of 3.56 MHz is preferred.

—Atmospheric Pressure Plasma Treatment—

Next, the atmospheric pressure plasma will be described. The atmospheric pressure plasma is a method of generating a stable plasma discharge at atmospheric pressure using high frequency waves.

In the atmospheric pressure plasma, argon gas, helium gas or the like is used as a carrier gas, and a gas prepared by partly mixing oxygen gas or the like with the carrier gas is used.

The atmospheric pressure plasma treatment is preferably carried out at the atmospheric pressure or a pressure close to or below the atmospheric pressure, such as about 500 to 800 Torr.

Furthermore, the power supply frequency of the discharge is preferably 1 to 100 kHz, and more preferably about 1 to 10 kHz.

If the power supply frequency is less than 1 kHz, a stable discharge may not be obtained. On the contrary, if the power supply frequency is greater than 100 kHz, expensive apparatuses are required, and it may be disadvantageous in view of cost.

The discharge intensity of the atmospheric pressure plasma treatment of the invention is preferably about 50 W·min/m² to 500 W·min/m². If the intensity is greater than 500 W·min/m², an arc discharge is also generated, and thus a stable treatment may not be carried out. Furthermore, if the intensity is less than 50 W·min/m², a sufficient treatment effect may not be obtained.

—Undercoat Layer—

The undercoat layer of the invention is a layer which contains a binder, and is provided on at least one surface of the polymer support to a thickness of 0.05 to 10 μm, to thereby increase the adhesiveness between the polymer support and the fluorine-containing polymer layer. The undercoat layer of the invention will be more specifically described below.

(Binder)

Examples of the binder (binding resin) that mainly constitutes the undercoat layer include a polyester resin, a polyurethane resin, an acrylic resin, a polyolefin resin, and a silicone resin. Among these, from the viewpoint of securing high adhesiveness between the polymer support (substrate) and the fluorine-containing polymer layer, the binder preferably contains at least one selected from the group consisting of polyolefins, acrylic resins and silicone resins, and more preferably contains an acrylic resin or a polyolefin resin. Furthermore, a composite resin may also be used, and for example, an acrylic/silicone composite resin is also a preferable binder.

The binder that is contained in the undercoat layer is preferably an acrylic resin, a polyester resin or a polyurethane resin, each of which has a solubility parameter of 9.5 to 14.0 (cal/cm³)^{0.5}. When the solubility parameter of these resins is in the range of from 9.5 (cal/cm³)^{0.5} to 14.0 (cal/cm³)^{0.5}, satisfactory adhesiveness is obtained. If the solubility parameter is beyond this range, adhesiveness is decreased.

The solubility parameter may be determined by the following formula, based on the solubility of the polymer in various solvents and mixed solvents with known solubility parameters.

Solubility parameter of a binder=(δ1+δ2)/2

δ1 represents the largest solubility parameter value obtainable from a solvent that is capable of dissolving the binder; and

δ2 represents the smallest solubility parameter value obtainable from a solvent that is capable of dissolving the binder.

δ1 may be determined by using, for example, a mixed solvent of acetone and methyl alcohol with varying mixing ratios, and δ2 may be determined by using, for example, a mixed solvent of acetone and n-hexane with varying mixing ratios.

The silicone resin represents a polymer that has a siloxane bond in the main or side chain thereof. As the silicone resin, a composite polymer that contains a polymer having the siloxane bond and the other polymer (for instance, an acryl polymer) as a copolymer ingredient, is preferable. The composite polymer according to the invention may be a block copolymer in which a polysiloxane and at least one polymer are copolymerized. The polysiloxane and the polymer that is copolymerized may be respectively composed of a single compound, or may be composed of two or more kinds

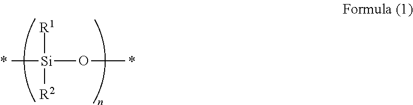

In Formula (I), R¹ and R² each independently represent a hydrogen atom, a halogen atom, a hydroxyl group, or a monovalent organic group. Herein, R¹ and R² may be identical with or different from each other. Plural R¹s may be identical with or different from each other, and plural R²s may be identical with or different from each other. n represents an integer of 1 or more.

In the “—(Si(R¹)(R²)—O)ₙ—” moiety ((poly)siloxane structural unit represented by Formula (I) above), which is a polysiloxane segment in the composite polymer, R¹ and R² may be identical with or different from each other, and respectively represent a hydrogen atom, a halogen atom, a hydroxyl group, or a monovalent organic group capable of covalent bonding with a Si atom.

The moiety “—(Si(R¹)(R²)—O)ₙ—” is a polysiloxane segment derived from various polysiloxanes having a straight chain, branched or cyclic structure.

Examples of the halogen atom represented by R¹ and R² include a fluorine atom, a chlorine atom, and an iodine atom.

The “monovalent organic group capable of covalent bonding with a Si atom,” which is represented by R¹ and R², may be unsubstituted or may be substituted. Examples of the monovalent organic group include an alkyl group (for example, a methyl group or an ethyl group), an aryl group (for example, a phenyl group), an aralkyl group (for example, a benzyl group or a phenylethyl group), an alkoxy group (for example, a methoxy group, an ethoxy group, or a propoxy group), an aryloxy group (for example, a phenoxy group), a mercapto group, an amino group (for example, an amino group or a diethylamino group), and an amido group.

Among them, from the viewpoints of adhesiveness to an adjacent material such as a polymer base material, and durability in a hot and humid environment, R¹ and R² are each independently preferably a hydrogen atom, a chlorine atom, a bromine atom, an unsubstituted or substituted alkyl group having 1 carbon atom to 4 carbon atoms (particularly, a methyl group or an ethyl group), an unsubstituted or substituted phenyl group, an unsubstituted or substituted alkoxy group, a mercapto group, an unsubstituted amino group, or an amido group, and more preferably an unsubstituted or substituted alkoxy group (preferably, an alkoxy group having 1 to 4 carbon atoms), from the viewpoint of durability in a hot and humid environment.

n is preferably 1 to 5,000, and more preferably 1 to 1,000.

The proportion of the —(Si(R¹)(R²)—O)ₙ— moiety (polysiloxane moiety represented by Formula (1)) in the composite polymer is preferably 15% by mass to 85% by mass relative to the total mass of the composite polymer, and inter alia, from the viewpoints of adhesiveness to the polymer base material and durability in a hot and humid environment, the proportion is more preferably in the range of 20% by mass to 80% by mass.

If the proportion of the polysiloxane moiety is 15% by mass or greater, the adhesiveness to the polymer base material and the adhesion durability upon exposure to a hot and humid environment are excellent. If the proportion is 85% by mass or less, when the composite polymer is used in a water dispersion, the stable dispersion effectively maintained.

There are no particular limitations on the polymer structural moiety that is copolymerized with the polysiloxane moiety as far as the polymer structural moiety contains no polysiloxane moiety, and the polymer structural moiety may be any polymer segment derived from any arbitrary polymer. Examples of a polymer that serves as a precursor of the polymer segment (precursor polymer) include various polymers such as a vinyl-based polymer (for example, an acrylic polymer), a polyester-based polymer, and a polyurethane-based polymer. From the viewpoints that preparation is easy and resistance to hydrolysis is excellent, a vinyl-based polymer and a polyurethane-based polymer are preferable, a vinyl-based polymer is more preferable, and an acrylic polymer is particularly preferable.

Representative examples of the vinyl-based polymer include various polymers such as an acrylic polymer, a carboxylic acid-vinyl ester-based polymer, an aromatic vinyl-based polymer and a fluoro-olefin-based polymer. Among them, from the viewpoints of the degree of freedom in design, an acrylic polymer (that is, an acrylic polymer structural moiety as the non-polysiloxane structural moiety) is particularly preferable.

In addition, the polymers that constitute the polymer structural moiety may be used alone, or two or more kinds may be used in combination.

Furthermore, the precursor polymer that constitutes the polymer structural moiety preferably contains at least one of an acid group and a neutralized acid group, and/or a hydrolyzable silyl group. Among such precursor polymers, a vinyl-based polymer can be prepared by using various methods such as, for example, (a) a method of copolymerizing a vinyl-based monomer containing an acid group, and a vinyl-based monomer containing a hydrolyzable silyl group and/or a silanol group, with a monomer capable of being copolymerized with these monomers; (2) a method of allowing a vinyl-based polymer containing a hydroxyl group and a hydrolyzable silyl group and/or a silanol group, which has been prepared in advance, to react with a polycarboxylic acid anhydride; and (3) a method of allowing a vinyl-based polymer containing an acid anhydride group and a hydrolyzable silyl group and/or a silanol group, which has been prepared in advance, to react with a compound having active hydrogen (water, alcohol, amine or the like).

Such a precursor polymer can be produced and obtained by using the method described in, for example, paragraphs [0021] to [0078] of JP-A No. 2009-52011.

The synthetic method of the composite polymer of the exemplary embodiment of the invention is described in, for example, the document of JP-A No. 11-209693.

The undercoat layer according to the invention may use the composite polymer alone as a binder, or may use the composite polymer in combination with another polymer. When another polymer is used in combination, the proportion of the composite polymer according to the invention is preferably 30% by mass or greater, and more preferably 60% by mass or greater, based on the total amount of binders. When the proportion of the composite polymer is 30% by mass or greater, the polymer layer is excellent in the adhesiveness to the polymer base material and the durability in a hot and humid environment.

A weight average molecular weight of the composite polymer is preferably in a range of 5,000 to 100,000, and more preferably in a range of 10,000 to 50,000.

For the preparation of the composite polymer, methods such as (i) a method of allowing a precursor polymer to react with the polysiloxane having a structure of “—(Si(R¹)(R²)—O)ₙ—”, and (ii) a method of subjecting a silane compound having the structure of “—(Si(R¹)(R²)—O)ₙ—” in which R¹ and/or R² is a hydrolyzable group, to hydrolysis and condensation in the presence of a precursor polymer, can be used.

Examples of the silane compound used in the method (ii) include various silane compounds, but an alkoxysilane compound is particularly preferable.

In the case of preparing a composite polymer by the method (i), the composite polymer can be prepared by, for example, allowing a mixture of a precursor polymer and a polysiloxane to react, while optionally adding water and a catalyst, at a temperature of about 20° C. to 150° C. for about 30 minutes to 30 hours (preferably, at 50° C. to 130° C. for 1 hour to 20 hours). As the catalyst, various silanol condensation catalysts such as an acidic compound, a basic compound, and a metal-containing compound, can be added.

Furthermore, in the case of preparing a composite polymer by the method (ii), the composite polymer can be prepared by, for example, adding water and a silanol condensation catalyst to a mixture of a precursor polymer and an alkoxysilane compound, and subjecting the mixture to hydrolysis and condensation at a temperature of about 20° C. to 150° C. for about 30 minutes to 30 hours (preferably, at 50° C. to 130° C. for 1 to 20 hours).

Examples of the silicone resin include: “CERANATE WSA1060” and “CERANATE WSA1070” (trade names: both are manufactured by DIC Corp.); and “H7620”, “H7630”, and “H7650” (trade names: all of them are manufactured by Asahi Kasei Chemicals Corp.).

(Other Additives)

The undercoat layer of the invention may also contain a crosslinking agent, a surfactant, a filler, and the like as necessary.

(Crosslinking Agent)

When a crosslinking agent is added to the binder (binding resin) that mainly constitutes an undercoat layer, and thus an undercoat layer is formed, a crosslinked structure originating from the crosslinking agent is obtained.

Examples of the crosslinking agent include epoxy-based, isocyanate-based, melamine-based, carbodiimide-based, and oxazoline-based crosslinking agents. Among these, carbodiimide-based and oxazoline-based crosslinking agents are preferred. Specific examples of the carbodiimide-based and oxazoline-based crosslinking agents include, as an example of the carbodiimide-based crosslinking agent, CARBODILITE V-02-L2 (trade name, manufactured by Nisshinbo Holdings, Inc.), and as examples of the oxazoline-based crosslinking agent, EPOCROS WS-700 and EPOCROS K-2020E (trade names, all manufactured by Nippon Shokubai Co., Ltd.).

The amount of addition of the crosslinking agent is preferably 0.5% to 25% by mass, and more preferably 2% to 20% by mass, relative to the amount of the binder that constitutes the undercoat layer. When the amount of addition of the crosslinking agent is 0.5% by mass or greater, a sufficient crosslinking effect is obtained while the strength and adhesiveness of the undercoat layer are retained. When the amount of addition is 25% by mass or less, the pot life of the coating liquid may be maintained long.

(Surfactant)

As the surfactant, any known anionic or nonionic surfactant may be used. In the case of adding a surfactant, the amount of addition thereof is preferably 0.1 to 10 mg/m², and more preferably 0.5 to 3 m g/m². When the amount of addition of the surfactant is 0.1 mg/m² or greater, the occurrence of cissing is suppressed, and satisfactory layer formation may be achieved. When the amount of addition is 10 mg/m² or less, the adhesion of the polymer support and the fluorine-containing polymer layer may be achieved satisfactorily.

(Filler)

The undercoat layer of the invention may also contain a filler. Examples of the filler that may be used include known fillers such as colloidal silica and titanium dioxide.

The amount of addition of the filler is preferably 20% by mass or less, and more preferably 15% by mass or less, relative to the amount of the binder of the undercoat layer. When the amount of addition of the filler is 20% by mass or less, the surface state of the undercoat layer may be maintained more satisfactorily.

The undercoat layer of the invention can serve as a refractive layer by containing a white pigment. Preferable examples of the white pigment include titanium dioxide, barium sulfate, silicon oxide, aluminum oxide, magnesium oxide, calcium carbonate, kaolin, and talc.

The content of the white pigment in the undercoat layer is preferably in the range of from 4 g/m² to 12 g/m², more preferably in the range of from 5 g/m² to 8 g/m².

(Thickness)

The thickness of the undercoat layer of the invention is 0.05 to 10 μm. If the thickness of the undercoat layer is less than 0.05 μm, durability is insufficient, and an adhesive force between the polymer support and the fluorine-containing polymer layer may not be secured. On the other hand, if the thickness of the undercoat layer is greater than 10 μm, the surface state is deteriorated, and the adhesive force between the undercoat layer and the fluorine-containing polymer layer is insufficient. When the thickness of the undercoat layer is in the range of 0.05 to 10 μm, the undercoat layer has a good balance between durability and surface state, and the adhesiveness between the polymer support and the fluorine-containing polymer layer may be increased. Thus, the thickness of the undercoat layer is particularly preferably in the range of about 1.0 to 10 μm.

Furthermore, when an acrylic resin, a polyester resin or a polyurethane resin, all of which have a solubility parameter of 9.5 to 14.0 (cal/cm³)^{0.5}, is used as a binder for forming an undercoat layer, the thickness of the undercoat layer is preferably 0.5 to 8.0 μm.

(Method for Formation)

The undercoat layer of the invention may be formed by applying a coating liquid containing a binder and the like on the polymer support, and drying the coating liquid. After drying, the coating liquid may be cured by heating or the like. There are no particular limitations on the coating method or on the solvent of the coating liquid used.

As the method of coating, for example, a gravure coater or a bar coater may be used.

The solvent used in the coating liquid may be water, or may be an organic solvent such as toluene or methyl ethyl ketone. One kind of a solvent may be used alone, or two or more kinds may be used in mixture. A method of forming an aqueous coating liquid in which the binder is dispersed in water and applying this aqueous coating liquid is preferred. In this case, the proportion of water in the solvent is preferably 60% by mass or greater, and more preferably 80% by mass or greater.

Furthermore, when the polymer support is a biaxially stretched film, a coating liquid intended for forming an undercoat layer may be applied on a polymer support obtained after biaxial stretching, and then the coating film thus formed may be dried. Alternatively, a method of applying a coating liquid on a polymer support obtained after uniaxial stretching, drying the coating film thus formed, and then stretching the polymer support in a direction different from the direction of the first stretching, may also be used. Furthermore, a coating liquid may be applied on a polymer support prior to stretching, and after the coating film thus formed is dried, the polymer support may be stretched in two directions.

—Fluorine-Containing Polymer Layer—

The fluorine-containing polymer layer of the invention is a layer which contains a binder including at least a fluorine-based polymer, and is provided to a thickness of 0.8 to 12 μm, in contact with the undercoat layer on at least one surface of the polymer support. Thus, the fluorine-containing polymer layer is directly provided on the undercoat layer. The fluorine-containing polymer layer is composed of a fluorine-based polymer (fluorine-containing polymer) as a main binder. The main binder is a binder which is contained in the fluorine-containing polymer layer in the largest amount. The fluorine-containing polymer layer of the invention will be more specifically described below.

(Fluorine-Based Polymer)

There are no particular limitations on the fluorine-based polymer used in the fluorine-containing polymer layer of the invention, as long as the fluorine-based polymer is a polymer having a repeating unit represented by formula: —(CFX¹—CX²X³)— (wherein X¹, X² and X³ each independently represent a hydrogen atom, a fluorine atom, a chlorine atom, or a perfluoroalkyl group having 1 to 3 carbon atoms). Specific examples of the polymer include polytetrafluoroethylene (hereinafter, may be indicated as PTFE), polyvinyl fluoride (hereinafter, may be indicated as PVF), polyvinylidene fluoride (hereinafter, may be indicated as PVDF), polychlorotrifluoroethylene (hereinafter, may be indicated as PCTFE), and polytetrafluoropropylene (hereinafter, may be indicated as HFP).

Such a polymer may be a homopolymer obtained by polymerizing a single monomer, or may be a copolymer of two or more kinds. Examples of this copolymer include a copolymer obtained by copolymerizing tetrafluoroethylene and tetrafluoropropylene (abbreviated to P(TFE/HFP)), and a copolymer obtained by copolymerizing tetrafluoroethylene and vinylidene fluoride (abbreviated to P(TFE/VDF)).

The polymer that is used in the fluorine-containing polymer layer of the invention may be a polymer obtained by copolymerizing a fluorine-based polymer represented by formula —(CFX¹—CX²X³)— and another monomer. Examples of this copolymer include a copolymer of tetrafluoroethylene and ethylene (abbreviated to P(TFE/E)), a copolymer of tetrafluoroethylene and propylene (abbreviated to P(TFE/P)), a copolymer of tetrafluoroethylene and vinyl ether (abbreviated to P(TFE/VE)), a copolymer of tetrafluoroethylene and perfluorovinyl ether (abbreviated to P(TFE/FVE)), a copolymer of chlorotrifluoroethylene and vinyl ether (abbreviated to P(CTFE/VE)), and a copolymer of chlorotrifluoroethylene and perfluorovinyl ether (abbreviated to P(CTFE/FVE)).

These fluorine-based polymers may be polymers that are used in the form of a solution of a polymer in an organic solvent, or may be polymers that are used in the form of a dispersion of polymer particles in water. Because of environmental burden, a dispersion of polymer particles in water is preferred. Examples of aqueous dispersions of fluorine-based polymers include those described in JP-A No. 2003-231722, JP-A No. 2002-20409, and JP-A No. 9-194538.

As the binder of the fluorine-containing polymer layer of the invention, the fluorine-based polymers may be used singly, or two or more kinds may be used together. Furthermore, a resin other than a fluorine-based polymer, such as an acrylic resin, a polyester resin, a polyurethane resin, a polyolefin resin, and a silicone resin, may also be used in combination to an extent of not exceeding 50% by mass of the total amount of the binder. However, if the amount of the resin other than a fluorine-based polymer is greater than 50% by mass, weather resistance may decrease when the binder is used in a back sheet.

(Other Additives)

The fluorine-containing polymer layer of the invention may also contain a crosslinking agent, a surfactant, a filler and the like, if necessary.

(Crosslinking Agent)

When a fluorine-containing polymer layer is formed by adding a crosslinking agent to a fluorine-containing polymer layer, a crosslinked structure originating from the crosslinking agent is obtained.

Examples of the crosslinking agent of the fluorine-containing polymer layer include epoxy-based, isocyanate-based melamine-based carbodiimide-based and oxazoline-based crosslinking agents. Among these, carbodiimide-based and oxazoline-based crosslinking agents are preferred. Examples of the carbodiimide-based crosslinking agents include, as an example of the carbodiimide-based crosslinking agent, CARBODILITE V-02-L2 (trade name, manufactured by Nisshinbo Holdings, Inc.), and as examples of the oxazoline-based crosslinking agent, EPOCROS WS-700 and EPOCROS K-2020E (trade names, all manufactured by Nippon Shokubai Co., Ltd.).

The amount of addition of the crosslinking agent is preferably 0.5% to 25% by mass, and more preferably 2% to 20% by mass, relative to the amount of the binder contained in the fluorine-containing polymer layer. When the amount of addition of the crosslinking agent is 0.5% by mass or greater, a sufficient crosslinking effect is obtained while the strength and adhesiveness of the fluorine-containing polymer layer are retained. When the amount of addition is 25% by mass or less, the pot life of the coating liquid may be maintained long.

(Surfactant)

As the surfactant for the fluorine-containing polymer layer, any known anionic or nonionic surfactant may be used. In the case of adding a surfactant, the amount of addition thereof is preferably 0.1 to 15 mg/m², and more preferably 0.5 to 5 mg/m². When the amount of addition of the surfactant is 0.1 mg/m² or greater, the occurrence of cissing is suppressed, and satisfactory layer formation may be achieved. When the amount of addition is 15 mg/m² or less, adhesion may be achieved satisfactorily.

(Filler)

The fluorine-containing polymer layer of the invention may also contain a filler. Examples of the filler that may be used include known fillers such as colloidal silica and titanium dioxide. The amount of addition of the filler is preferably 20% by mass or less, and more preferably 15% by mass or less, relative to the amount of the binder of the undercoat layer. When the amount of addition of the filler is 20% by mass or less, the surface state of the fluorine-containing polymer layer may be maintained more satisfactorily.

(Thickness)

The thickness of the fluorine-containing polymer layer of the invention is in the range of 0.8 to 12 μm. If the thickness of the fluorine-containing polymer layer is less than 0.8 μm, durability (weather resistance) of the polymer sheet for solar cell back sheets, particularly as the outermost layer, is insufficient, and if the thickness of the fluorine-containing polymer layer is greater than 12 μm, the surface state is deteriorated, and the adhesive force between the fluorine-containing polymer layer and the undercoat layer is insufficient. When the thickness of the fluorine-containing polymer layer is in the range of 0.8 to 12 μm, the fluorine-containing polymer layer has a good balance between durability and surface state. Thus, the thickness of the fluorine-containing polymer layer is particularly preferably in the range of about 1.0 to 10 μm.

(Position)

The polymer sheet for solar cell back sheets of the invention may be such that another layer may be laminated on the fluorine-containing polymer layer, but from the viewpoints of an enhancement of durability, weight reduction, slimming, cost reduction and the like of the polymer sheet for back sheets, it is preferable that the fluorine-containing polymer layer be the outermost layer of the polymer sheet for back sheets.

(Method for Formation)

The fluorine-containing polymer layer may be formed by applying a coating liquid containing the fluorine-based polymer and the like that constitute the fluorine-containing polymer layer, on the undercoat layer, and drying the coating film thus formed. After drying, the fluorine-containing polymer layer may be cured by heating or the like. There are no particular limitations on the coating method or the solvent of the coating liquid.

As the coating method, for example, a gravure coater or a bar coater may be used.

The solvent used in the coating liquid may be water, or may be an organic solvent such as toluene or methyl ethyl ketone. One kind of a solvent may be used alone, or two or more kinds may be used in mixture. However, a method of forming an aqueous coating liquid in which a binder such as a fluorine-based polymer is dispersed in water and applying this aqueous coating liquid is preferred. In this case, the proportion of water in the solvent is preferably 60% by mass or greater, and more preferably 80% by mass or greater. When the solvent contained in the coating liquid that forms the fluorine-containing polymer layer contains 60% by mass or more of water, the environmental burden is reduced, which is preferable.

The polymer sheet for solar cell back sheets of the invention may further have other layers, if necessary. For example, a colored layer may be provided on the opposite side of the side where the fluorine-containing polymer layer is provided in the polymer support.

—Colored Layer—

The colored layer contains at least a pigment and a binder, and may be constituted to further include other components such as various additives as necessary.

The functions of the colored layer may include, firstly, an enhancement of the power generation efficiency of solar cell modules by reflecting a portion of incident light which passes through a photovoltaic cell and reaches the back sheet without being used in the power generation, to return the portion of light to the photovoltaic cell; and secondly, an enhancement of the decorative properties of the external appearance when the solar cell module is viewed from the side through which sunlight enters (front surface side). Generally, when a solar cell modules is viewed from the front surface side (glass substrate side), the back sheet is seen around the photovoltaic cell. Thus, when a colored layer is provided in the polymer sheet for back sheets, the decorative properties of the back sheet are improved, and thereby the appearance may be improved.

(Pigment)

The colored layer according to the invention contains at least one pigment.

As the pigment, for example, an inorganic pigment such as titanium dioxide, barium sulfate, silicon oxide, aluminum oxide, magnesium oxide, calcium carbonate, kaolin, talc, ultramarine blue, Prussian blue, or carbon black; or an organic pigment such as phthalocyanine blue or phthalocyanine green can be appropriately selected and incorporated.

In the case where the colored layer is constructed as a reflective layer which reflects the light that has entered a solar cell and passed through the photovoltaic cell, and returns the light to the photovoltaic cell, it is preferable that the colored layer contain a white pigment. Preferable examples of the white pigment include titanium dioxide, barium sulfate, silicon oxide, aluminum oxide, magnesium oxide, calcium carbonate, kaolin, and talc.

The content of the pigment in the colored layer is preferably in the range of 2.5 to 8.5 g/m². When the content of the pigment is 2.5 g/m² or greater, necessary coloration may be achieved, and a desired reflection ratio or decorative properties may be effectively imparted to the colored layer. Furthermore, when the content of the pigment in the colored layer is 8.5 g/m² or less, the surface state of the colored layer may be easily maintained satisfactory, and the film strength is more excellent. Among these values, the content of the pigment is more preferably in the range of 4.5 to 8.0 g/m².

The volume average particle diameter of the pigment is preferably 0.03 μm to 0.8 μm, and more preferably about 0.15 μm to 0.5 μm. When the average particle diameter is in the range mentioned above, the efficiency of light reflection is high. The average particle diameter is a value measured with a laser analysis/scattering type particle diameter distribution measuring apparatus LA950 (trade name, manufactured by Horiba, Ltd.).

Examples of the binder that constitutes the colored layer include a polyester resin, a polyurethane resin, an acrylic resin, a polyolefin resin, and a silicone resin. Among these, an acrylic resin and a polyolefin resin are preferred from the viewpoint of securing high adhesiveness. Furthermore, a composite resin may also be used, and for example, an acrylic/silicone composite resin is another preferable binder. The content of the binder is preferably in the range of 15% by mass to 200% by mass, and more preferably in the range of 17% by mass to 100% by mass, based on the content of the pigment. When the content of the binder is 15% by mass or more, the strength of the colored layer is sufficiently obtained, and when the content is 200% by mass or less, the reflectance or decorativeness can be maintained satisfactorily.

(Additives)

The colored polymer layer of the invention may further contain a crosslinking agent, a surfactant, a filler, and the like as necessary.

Examples of the crosslinking agent include epoxy, isocyanate, melamine, carbodiimide and oxazoline crosslinking agents. The amount added is preferably 5% by mass to 50% by mass, and more preferably 10% by mass to 40% by mass, based on the content of the binder in the colored layer. When the amount of the crosslinking agent added is 5% by mass or greater, a sufficient crosslinking effect is obtained while the strength and adhesiveness of the colored layer is retained. When the amount added is 50% by mass or less, a prolonged pot life of the coating liquid can be maintained.

The surfactant such as known anionic or nonionic surfactants can be used. When a surfactant is added, the amount added is preferably 0.1 mg/m² to 15 mg/m², and more preferably 0.5 mg/m² to 5 mg/m². When the amount of the surfactant added is 0.1 mg/m² or greater, the occurrence of cissing is suppressed, and satisfactory layer formation may be achieved. When the amount added is 15 mg/m² or less, the adhesion can be satisfactorily achieved.

The colored layer may further contain a filler. The amount of addition of the filler is preferably 20% by mass or less, and more preferably 15% by mass or less based on the content of the binder in the colored layer. When the amount of addition of the filler is 20% by mass or less, the surface state of the colored layer may be maintained more satisfactorily.

(Method for Forming Colored Layer)

The formation of the colored layer can be carried out by a method of affixing a polymer sheet containing a pigment to a polymer support; a method of co-extruding the colored layer during the formation of the substrate; a method based on coating; or the like. Specifically, the colored layer can be formed directly, or via an undercoat layer having a thickness of 2 μm or less, on the surface of a polymer support by performing affixing, co-extruding, coating or the like. The colored layer thus formed may be in a state of being in direct contact with the surface of the polymer substrate, or may be in a state of being laminated via an undercoat layer on the surface of the polymer substrate.

Among the methods described above, a method based on coating is preferable from the viewpoint that the method is convenient, and it is possible to form a uniform thin film. In the case of performing coating, known coating methods using, for example, a gravure coater or a bar coater can be used.

The coating liquid may be an aqueous type using water as a coating solvent, or a solvent type using an organic solvent such as toluene or methyl ethyl ketone. Among these, from the viewpoint of environmental load, it is preferable to use water as the solvent. The coating solvent may be such that one kind may be used alone, or two or more kinds may be used in mixture.

—Easy Adhesive Layer—

The polymer sheet for back sheets of the invention may be further provided with an easy adhesive layer on the surface of the side opposite to the surface where the fluorine-containing polymer layer is provided (particularly, on the colored layer). The easy adhesive layer is a layer intended for strong adhesion of the polymer sheet for back sheets to a sealing material that seals the photovoltaic element (hereinafter, also referred to as “power generating element”) of the substrate on the cell side (main body of the cell).

The easy adhesive layer may be formed by using a binder and inorganic fine particles, and may be formed to further include other components such as additives, if necessary. The easy adhesive layer is preferably constructed to have an adhesive force of preferably 5 N/cm or greater, and more preferably 10 N/cm or greater (even more preferably, 20 N/cm or greater) with respect to an ethylene-vinyl acetate (EVA; ethylene-vinyl acetate copolymer)-based sealing material that seals the power generating element of the substrate on the cell side. When the adhesive force is 5 N/cm or greater, particularly 10 N/cm or greater, moisture-heat resistance that makes it possible to maintain adhesiveness, is easily obtained.

The adhesive force may be adjusted by a method of regulating the amounts of the binder and the inorganic fine particles in the easy adhesive layer, a method of applying a corona treatment to the surface that is adhered to the sealing material of the polymer sheet for back sheets, or the like.

(Binder)

The easy adhesion layer can contain at least one binder.

Examples of the binder that is suitable for the easy adhesion layer include a polyester, a polyurethane, an acrylic resin, and a polyolefin. Among these, an acrylic resin and a polyolefin are preferable from the viewpoint of durability. Furthermore, a composite resin of acrylic resin and silicone is also preferable as the acrylic resin.

Preferable examples of the binder include, as specific examples of the polyolefin, CHEMIPEARL S-120 and S-75N (trade names, all manufactured by Mitsui Chemicals, Inc.); as specific examples of the acrylic resin, JURYMER ET-410 and SEK-301 (trade names, all manufactured by Nihon Junyaku Co., Ltd.); and as specific examples of the composite resin of acrylic resin and silicone, CERANATE WSA1060 and WSA1070 (trade names, all manufactured by DIC Corp.), H7620, H7630 and H7650 (trade names, all manufactured by Asahi Kasei Chemicals Corp.).

The content of the binder in the easy adhesive layer is preferably set in the range of 0.05 to 5 g/m². Among others, an amount in the range of 0.08 to 3 g/m² is more preferred. When the content of the binder is 0.05 g/m² or greater, a desired adhesive force may be easily obtained, and when the content of the binder is 5 g/m² or less, a more satisfactory surface state may be obtained.

(Fine Particles)

The easy adhesion layer can contain at least one kind of inorganic fine particles.

Examples of the inorganic fine particles include fine particles of silica, calcium carbonate, magnesium oxide, magnesium carbonate and tin oxide. Among these, the fine particles of tin oxide and silica are preferable from the viewpoint that the decrease in adhesiveness is small when the easy adhesion layer is exposed to a hot and humid atmosphere.

The volume average particle diameter of the inorganic fine particles is preferably about 10 nm to 700 nm, and more preferably about 20 nm to 300 nm. When the particle diameter is in this range, more satisfactory adhesiveness can be obtained. The particle diameter is a value measured with a laser analysis/scattering type particle diameter distribution measuring apparatus LA950 (trade name, manufactured by Horiba, Ltd.).

There are no particular limitations on the shape of the inorganic fine particles, and any of a spherical shape, an amorphous shape, a needle shape and the like can be used.

The content of the inorganic fine particles is in the range of 5% by mass to 400% by mass, based on the content of the binder in the easy adhesion layer. If the content of the inorganic fine particles is less than 5% by mass, satisfactory adhesiveness cannot be retained when the easy adhesion layer is exposed to a hot and humid atmosphere, and if the content is greater than 400% by mass, the surface state of the easy adhesion layer is deteriorated.

Among these, the content of the inorganic fine particles is preferably in the range of 50% by mass to 300% by mass.

(Crosslinking Agent)

The easy adhesion layer can contain at least one crosslinking agent.

Examples of a crosslinking agent that is suitable for the easy adhesion layer include epoxy, isocyanate, melamine, carbodiimide and oxazoline crosslinking agents. Among these, from the viewpoint of securing adhesiveness after a lapse of time under heat and moisture, an oxazoline crosslinking agent is particularly preferable.

Specific examples of the oxazoline crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), bis-(2-oxazolinylcyclohexane) sulfide, and bis-(2-oxazolinylnorbornane) sulfide. Furthermore, (co)polymers of these compounds are also preferably used.

As the compound having an oxazoline group, EPOCROS K2010E, EPOCROS K2020E, EPOCROS K2030E, EPOCROS WS-500, EPOCROS WS-700 (trade names, all manufactured by Nippon Shokubai co., Ltd.) and the like can also be used.

The content of the crosslinking agent in the easy adhesion layer is preferably 5% by mass to 50% by mass based on the content of the binder in the easy adhesion layer, and among these, more preferably 20% by mass to 40% by mass. When the content of the crosslinking agent is 5% by mass or greater, a satisfactory crosslinking effect is obtained, and the strength or adhesiveness of the colored layer can be maintained. When the content is 50% by mass or less, a prolonged pot life of the coating liquid can be maintained.

(Additives)

The easy adhesion layer according to the invention may optionally contain a known matting agent such as polystyrene, polymethyl methacrylate or silica; a known anionic or nonionic surfactant; and the like.

(Method of Forming Easy Adhesion Layer)

The formation of the easy adhesion layer may be carried out by a method of affixing a polymer sheet having easy adhesiveness to a substrate, or a method based on coating. Among these, the method based on coating is preferable from the viewpoint that the method is convenient, and it is possible to form a uniform thin film.

In regard to the coating method, known coating methods using, for example, a gravure coater or a bar coater can be used.

The coating solvent used in the preparation of the coating liquid may be water, or may be an organic solvent such as toluene or methyl ethyl ketone. The coating solvent may be such that one kind may be used alone, or two or more kinds may be used in a mixture.

(Properties)

There are no particular limitations on the thickness of the easy adhesion layer, but the thickness is usually preferably 0.05 μm to 8 μm, and more preferably in the range of 0.1 μm to 5 μm. When the thickness of the easy adhesion layer is 0.05 μm or greater, the necessary adhesiveness can be suitably obtained, and when the thickness is 8 μm or less, the surface state becomes more satisfactory.

Furthermore, the easy adhesion layer of the invention needs to be transparent in order not to reduce the effect of the colored layer.

<Method for Producing Polymer Sheet for Solar Cell Back Sheets>

There are no particular limitations on the method for producing a polymer sheet for solar cell back sheets of the invention, but the production may be suitably carried out by the following processes.

That is, a preferable method for producing a polymer sheet for solar cell back sheets includes:

a step of preparing a polymer sheet provided with the undercoat layer on at least one surface of the polymer support;

a step of applying, on the undercoat layer, a coating liquid which contains a binder including the fluorine-based polymer and contains water in an amount of 60% by mass or greater of the total amount of the solvent; and

a step of drying the coating liquid applied on the undercoat layer to form the fluorine-containing polymer layer.

Furthermore, when the coating liquid applied on the undercoat layer was dried to form the fluorine-containing polymer layer, and then the fluorine-containing polymer layer is cured, the adhesiveness after a lapse of time under heat and moisture may be increased.

It is also preferable to form the undercoat layer by applying a coating liquid containing a binder on at least one surface of a polymer support, and then drying the coating liquid applied on the polymer support.

The polymer sheet of the invention may further optionally contain other layers (a readily adhesive layer, and the like) if necessary, as described above. Therefore, the method for producing a polymer sheet of the invention may include steps for forming other layers, in addition to the above-described indispensable steps.

An example of an embodiment for formation of another layer may be (1) a method of forming another layer by applying a coating liquid containing the components that constitute the other layer on a surface where layer forming is desired (for example, a surface opposite to the surface where the undercoat layer and fluorine-containing polymer layer of the polymer support of the polymer sheet of the invention are formed). For example, the method described above as a method for forming a readily adhesive layer and a colored layer may be used.

Specific examples of the polymer sheet of the invention formed by such a method include a polymer sheet provided with a reflective layer which contains a white pigment, on the surface opposite to the surface where the fluorine-containing polymer layer of the polymer sheet of the invention is formed; a polymer sheet provided with a colored layer which contains a coloring pigment, on the surface opposite to the surface where the fluorine-containing polymer layer of the polymer sheet of the invention is formed; and a polymer sheet provided with a reflective layer which contains a white pigment and a readily adhesive layer, on the surface opposite to the surface where the fluorine-containing polymer layer of the polymer sheet of the invention is formed.

Another example of an embodiment for formation of another layer may be (2) a method of affixing a sheet having one or more layers that exhibit the functions desired of the other layers, to a surface where layer forming is desired.

The sheet that is used in the case where the method (2) is applied is a sheet having one or more other layers, and examples thereof include a sheet in which a polymer film containing a white pigment is affixed to the surface opposite to the surface where the fluorine-containing polymer layer of the polymer sheet of the invention is formed; a sheet in which a colored film containing a coloring pigment is affixed to the surface opposite to the surface where the fluorine-containing polymer layer of the polymer sheet of the invention is formed; a sheet in which an aluminum thin film and a polymer film containing a white pigment are affixed to the surface opposite to the surface where the fluorine-containing polymer layer of the polymer sheet of the invention is formed; and a sheet in which a polymer film having an inorganic barrier layer and a polymer film containing a white pigment are affixed to the surface opposite to the surface where the fluorine-containing polymer layer of the polymer sheet of the invention is formed.

<Back Sheet for Solar Cells>

The back sheet for solar cells of the invention is constructed by providing the polyester film of the invention as described above, and for example, can be constructed by providing a colored layer on a one side of the polymer support of the invention or further providing a barrier layer or a metal sheet.

The barrier layer is provided in order for moisture not to permeate EVA (sealant) or the solar cell. Any material that moisture does not substantially permeate can be used. However, from the viewpoints of weight, cost and flexibility, silicone deposited PET sheet, silicon oxide deposited PET sheet or aluminum oxide deposited PET sheet or the like are used. The thickness of the barrier layer is generally from about 10 μm to 30 μm.

The metal sheet is used for the same object as the barrier sheet and metal thin sheet such as aluminum or stainless steel are used. In the case of metal sheet, the thickness is generally from about 10 μm to 30 μm

The back sheet for solar cells of the invention is constructed by another polymer sheet attached, via an adhesive, to a surface opposite to the surface where the fluorine-containing polymer layer of the polymer sheet of the invention are formed. Another polymer sheet to attach to the polymer sheet of the invention is not particularly limited. For example, a PET sheet containing white pigments which serves as a refractive layer can be used.

As the adhesive to attach a polymer sheet, two liquid curing type polyurethane resin based adhesive or the like (a resin cured by reacting a hydroxyl group (—OH) such as an alkyd resin, an acryl resin and a polyvinyl alcohol, with an isocyanate group (—NCO) of an isocyanate resin) is used.

Since the polyurethane resin based adhesive is prone to react with active hydrogen contained in many functional groups and has a superior solubility and wettability with an adherend, it has a high adhesiveness when used with a combination of many kinds of plastic films or sheets.

As an adhesive, for example, the two liquid curing type polyurethane resin based adhesive is mixed in a predetermined ratio and coated on one side or both sides of two surfaces to adhere, then contacted each other and pressed or dried after coating, superimposed and adhered by heat and pressure.

For the adhesive coating, known coaters such as a roll coater and a gravure coater can be used.

The amount of the adhesive is generally a range of from 2 g/m² to 20 g/m² based on the solid content. A lamination is conducted using known dry laminator or extrusion coater.

<Solar Cell Module>

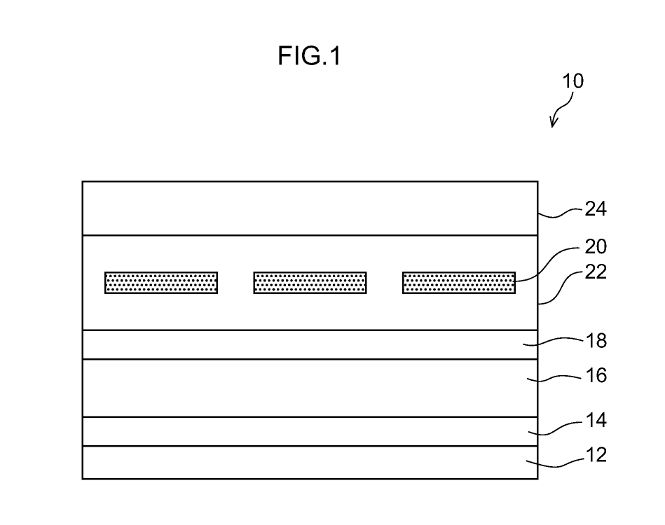

FIG. 1 schematically shows an exemplary configuration of the solar cell module of the invention. This solar cell module 10 has a configuration in which a solar cell element 20 which converts the light energy of sunlight to electrical energy, is disposed between a transparent substrate 24 through which sunlight enters and the polymer sheet for solar cell back sheets of the invention described above, the space between the substrate and the polymer sheet for back sheets is sealed with an ethylene-vinyl acetate-sealing material 22. The polymer sheet for back sheets of the exemplary embodiment is provided with a fluorine-containing polymer layer 12 in contact with an undercoat layer 14 on one surface of a polymer support 16, and is provided with a white reflective layer 18 as another layer on the other surface (the side through which sunlight enters).

The solar cell module, solar cell and members other than the back sheet are described in detail in, for example, “Constituent Materials for Solar Photovoltaic System” (edited by Sugimoto Eiichi, Kogyo Chosakai Publishing, Inc., published in 2008).

The transparent substrate 24 has light transmissivity capable of transmitting sunlight, and the substrate can be appropriately selected from materials that are capable of transmitting light. From the viewpoint of power generation efficiency, a substrate having higher light transmittance is more preferable, and as such a substrate, for example, a glass substrate, or a transparent resin such as an acrylic resin can be preferably used.

As the solar cell device 20, various known solar cell devices such as silicon-based devices such as single crystal silicon, polycrystalline silicon and amorphous silicon; and Group III-V or Group II-VI compound semiconductors such as copper-indium-gallium-selenium, copper-indium-selenium, cadmium-tellurium and gallium-arsenic, can be applied.

In a solar cell module 10 having such a configuration, since the fluorine-containing polymer layer which serves as the outermost layer is provided via an undercoat layer on the rear surface side, the solar cell module has high durability and also maintains high adhesiveness. Therefore, the solar cell module 10 may be used even in the outdoors for a long time period.

### EXAMPLES

Hereinafter, the invention will be explained more specifically by way of Examples, but the invention is not intended to be limited to the following Examples so long as the gist is maintained.

### Example 1

### Production of Substrate PET-1

—Synthesis of Polyester—

A slurry of 100 kg of high purity terephthalic acid (manufactured by Mitsui Chemicals, Inc.) and 45 kg of ethylene glycol (manufactured by Nippon Shokubai Co., Ltd.) was sequentially supplied over 4 hours into an esterification reaction tank which had been previously charged with about 123 kg of bis(hydroxyethyl) terephthalate and was maintained at a temperature of 250° C. and at a pressure of 1.2×10⁵ Pa. Even after the completion of supply, the esterification reaction was performed for another one hour. Thereafter, 123 kg of the esterification reaction product thus obtained was transferred to a polycondensation reaction tank.

Subsequently, ethylene glycol was added to the polycondensation reaction tank to which the esterification reaction product was transferred, in an amount of 0.3% by mass based on the mass of the polymer to be obtained. After stirring for 5 minutes, an ethylene glycol solution of cobalt acetate and an ethylene glycol solution of manganese acetate were added in an amount of cobalt of 30 ppm and in an amount of manganese of 15 ppm, respectively, in the polymer to be obtained. After stirring the mixture for a further 5 minutes, a 2 mass % ethylene glycol solution of a titanium alkoxide compound was added to the mixture in an amount of titanium of 5 ppm in the polymer to be obtained. As the titanium alkoxide compound, the titanium alkoxide compound (Ti content=4.44% by mass) which may be synthesized in Example 1 of paragraph [0083] of JP-A No. 2005-340616 was used. After 5 minutes, a 10% by mass ethylene glycol solution of ethyl diethylphosphonoacetate was added to the reaction system in an amount of 5 ppm based on the polymer thus obtainable.

Thereafter, while the lower polymer was stirred at 30 rpm, the temperature of the reaction system was slowly increased from 250° C. to 285° C., and the pressure was decreased to 40 Pa. The time taken to reach the final temperature and the final pressure was 60 minutes in total. At the time point when a predetermined stirring torque (97 kg·cm) was reached, the reaction system was purged with nitrogen, the pressure was returned to normal pressure, and the polycondensation reaction was terminated. Here, the time taken to reach a predetermined stirring torque from the initiation of pressure reduction was 3 hours.

The polymer molten product thus obtained was ejected into a strand form in cold water and was immediately cut. Thus, pellets (diameter: about 3 mm, length: about 7 mm) of the polymer were produced.

—Solid State Polymerization—

The pellets obtained as described above were maintained at a temperature of 220° C. for 30 hours in a vacuum container maintained at 40 Pa, and thereby solid state polymerization was carried out.

—Formation of Base—

The pellets after the solid state polymerization as described above were melted at 280° C. and cast on a metal drum, and thereby an unstretched base having a thickness of about 3 mm was produced. Subsequently, the unstretched base was stretched to 3 times in the length direction at 90° C. and was stretched to 3.3 times in the width direction at 120° C. Thereby, a biaxially stretched polyethylene terephthalate substrate (hereinafter, referred to as “PET-1 substrate”) having a thickness of 300 μm was obtained.

The carboxyl group content of this base was 29 mol/ton.

—Preparation of Pigment Dispersion—

The various components of the following composition were mixed, and the mixture was subjected to a dispersion treatment for one hour using a Dyno-Mill type dispersing machine.

(Composition of Pigment Dispersion)

| | |
|---|---|
| Titanium dioxide (volume average particle size = 0.42 μm) | 40% by mass |
| (trade name: TIPAQUE R-780-2, manufactured by Ishihara | |
| Sangyo Kaisha, Ltd.; solids content 100% by mass) | |
| Aqueous solution of polyvinyl alcohol (10% by mass) | 8.0% by mass |
| (trade name: PVA-105, manufactured by Kuraray Co., | |
| Ltd.) | |
| Surfactant (trade name: DEMOL EP, manufactured by Kao | 0.5% by mass |
| Corporation; 25% by mass) | |
| solids content: Distilled water | 51.5% by mass |

<Undercoat Layer>

—Preparation of Coating Liquid for Undercoat Layer Formation—

The various components of the following composition were mixed, and thus a coating liquid for undercoat layer formation was prepared.

(Composition of Coating Liquid)

| | |
|---|---|
| CERANATE WSA-1070 (binder, P-1) (trade name, | 362.3 parts by mass |
| acrylic/silicone-based binder, manufactured by DIC | |
| Corporation; solids content: 40% by mass) | |
| Carbodiimide compound (crosslinking agent, A-1) | 48.3 parts by mass |
| (trade name: CARBODILITE V-02-L2, manufactured | |
| by Nisshinbo Holdings, Inc.; solids content: 40% | |
| by mass) | |
| Surfactant (trade name: NAROACTY CL95, | 9.7 parts by mass |
| manufactured by Sanyo Chemical Industries, Ltd.; | |
| solids content: 1% by mass) | |
| Distilled water | 543.5 parts by mass |

—Formation of Undercoat Layer—

The coating liquid for undercoat layer formation thus obtained was applied on one surface of the PET substrate, such that the amount of binder in terms of the amount of application was 3.0 g/m², and the coating liquid was dried for one minute at 180° C. Thus, an undercoat layer having a dried thickness of about 3 μm was formed.

<Fluorine-Containing Polymer Layer>

—Preparation of Coating Liquid for Fluorine-Containing Polymer Layer Formation—

The various components of the following composition were mixed, and thus a coating liquid for fluorine-containing polymer layer formation was prepared.

(Composition of Coating Liquid)

| | |
|---|---|
| OBBLIGATO SSW0011F (binder, P-101) (trade | 247.8 parts by mass |
| name, fluorine-based binder, manufactured by AGC | |
| Coat-Tech Co., Ltd.; solids content: 39% by mass) | |
| Carbodiimide compound (crosslinking agent, A-1) | 24.2 parts by mass |
| (trade name: CARBODILITE V-02-L2, manufactured | |
| by Nisshinbo Holdings, Inc.; solids content: 40% | |
| by mass) | |
| Surfactant (trade name: NAROACTY CL95, | 24.2 parts by mass |
| manufactured by Sanyo Chemical Industries, Ltd.; | |
| solids content: 1% by mass) | |
| Distilled water | 703.8 parts by mass |

—Formation of Fluorine-Containing Polymer Layer—

The coating liquid for fluorine-containing polymer layer formation thus obtained was applied on the undercoat layer provided on one surface of the PET substrate, such that the amount of binder in terms of the amount of application was 2.0 g/m², and the coating liquid was dried for one minute at 180° C. Thus, a fluorine-containing polymer layer having a dried thickness of about 2 μm was formed.

The sample thus obtained was subjected to various evaluations on the retention rate of breaking elongation, adhesiveness before a lapse of time under heat and moisture, adhesiveness after a lapse of time under heat and moisture, durability, and surface state, which will be described below. These results are presented in Table 2.

### Comparative Examples 1 and 2, Examples 2 to 6

Comparative Examples 1 and 2, and Examples 2 to 6 were carried out in the same manner as in Example 1, except that the thickness of the undercoat layer was changed as indicated in Table 1. However, Comparative Example 1 was a sample without undercoat layer.

The results obtained by carrying out the same evaluations as in Example 1 on the samples thus obtained, are presented in Table 2.

### Examples 7 to 13

Examples 7 to 13 were carried out in the same manner as in Example 1, except that the crosslinking agent that was added to the undercoat layer was changed as indicated in Table 1. However, Example 7 was a sample which did not have any crosslinking agent added to the undercoat layer.

The results obtained by carrying out the same evaluations as in Example 1 on the samples thus obtained, are presented in Table 2.

### Comparative Examples 3 and 4, Examples 14 to 16

Comparative Examples 3 and 4, and Examples 14 to 16 were carried out in the same manner as in Example 1, except that the thickness of the fluorine-containing polymer layer was changed as indicated in Table 1.

The results obtained by carrying out the same evaluations as in Example 1 on the samples thus obtained, are presented in Table 2.

### Examples 17 to 22

Examples 17 to 22 were carried out in the same manner as in Example 1, except that the crosslinking agent that was added to the fluorine-containing polymer layer was changed as indicated in Table 1. However, Example 17 was a sample which did not have any crosslinking agent added to the fluorine-containing polymer layer.

The results obtained by carrying out the same evaluations as in Example 1 on the samples thus obtained, are presented in Table 2.

### Comparative Example 5, Examples 23 to 29

Comparative Example 5, and Examples 23 to 29 were carried out in the same manner as in Example 1, except that the binder and the crosslinking agent of the undercoat layer or the fluorine-containing polymer layer were changed as indicated in Table 1.

The results obtained by carrying out the same evaluations as in Example 1 on the samples thus obtained, are presented in Table 2.

### Example A

Example A was carried out in the same manner as in Example 1, except that the undercoat layer was changed as follows.

—Preparation of Pigment Dispersion 2—

The various components of the following composition were mixed, and the mixture was subjected to a dispersion treatment for one hour using a Dyno-Mill type dispersing machine.

(Composition of Pigment Dispersion 2)

| | |
|---|---|
| Titanium dioxide (volume average particle size = 0.42 μm) | 50.3% by mass |
| (trade name: TIPAQUE R-780-2, manufactured by | |
| Ishihara Sangyo Kaisha, Ltd.; solids content 100% by mass) | |
| Aqueous solution of polyvinyl alcohol (10% by mass) | 2.5% by mass |
| (trade name: PVA-105, manufactured by Kuraray Co., Ltd.) | |
| Surfactant (trade name: DEMOL EP, manufactured by Kao | 0.2% by mass |
| Corporation; solids content: 25% by mass) | |
| Distilled water | 47.0% by mass |

<Undercoat Layer>

—Preparation of Coating Liquid for Undercoat Layer Formation—

The various components of the following composition were mixed, and thus a coating liquid for undercoat layer formation was prepared.

(Composition of Coating Liquid)

| | |
|---|---|
| CERANATE WSA-1070 (binder, P-1) (trade name, | 350.0 parts by mass |
| acrylic/silicone-based binder, manufactured by DIC | |
| Corporation; solids content: 40% by mass) | |
| Carbodiimide compound (crosslinking agent, A-1) | 98.0 parts by mass |
| (trade name: CARBODILITE V-02-L2, manufactured | |
| by Nisshinbo Holdings, Inc.; solids content: 40% by | |
| mass) | |
| Oxazoline compound (trade name: EPOCROS | 16.8 parts by mass |
| WS-700, crosslinking agent, manufactured by Nippon | |
| Shokubai Co., Ltd.; solids content: 25%) | |
| Surfactant (trade name: NAROACTY CL95, | 15.0 parts by mass |
| manufactured by Sanyo Chemical Industries, Ltd.; | |
| solids content: 1% by mass) | |
| Pigment dispersion 2 | 456.6 parts by mass |
| Distilled water | 63.6 parts by mass |

—Formation of Undercoat Layer—

The coating liquid for undercoat layer formation thus obtained was applied on one surface of the PET substrate, such that the amount of binder in terms of the amount of application was 4.0 g/m², and the coating liquid was dried for one minute at 180° C. Thus, an undercoat layer having a dried thickness of about 4 μm was formed.

### Example B

Example B was carried out in the same manner as in Example A, except that the formula of pigment dispersion was changed as follows.

—Preparation of Pigment Dispersion 3—

The various components of the following composition were mixed, and the mixture was subjected to a dispersion treatment for one hour using a Dyno-Mill type dispersing machine.

(Composition of Pigment Dispersion 3)

| | |
|---|---|
| Titanium dioxide (volume average particle size = 0.28 μm) | 50.3% by mass |
| 100% by mass) (trade name: CR95, manufactured by | |
| Ishihara Sangyo Kaisha, Ltd.; solids content | |
| Aqueous solution of polyvinyl alcohol (10% by mass) | 2.5% by mass |
| (trade name: PVA-105, manufactured by Kuraray Co., Ltd.) | |
| Surfactant (trade name: DEMOL EP, manufactured by Kao | 0.2% by mass |
| Corporation; solids content: 25% by mass) | |
| Distilled water | 47.0% by mass |

### Example C

The following surface undercoat layer was coated on the surface of the polymer sheet opposite to the surface where the undercoat layer and the polymer layer were provided in Example A, and the reflective layer described below in Example 30 was provided on this surface. Thus, a back sheet sample for a solar cell was produced.

—Preparation of Coating Liquid for Surface Undercoat Layer Formation—

Various components of the following components were mixed, and thus a coating liquid for surface undercoat layer formation was prepared.

(Composition of Coating Liquid)

| | |
|---|---|
| Polyester binder (trade name: VYLONAL DM1245, | 48.0 parts by mass |
| manufactured by Toyobo Co., Ltd.; solids content 30% | |
| by mass) | |
| Carbodiimide compound (crosslinking agent) (trade | 10.0 parts by mass |
| name: CARBODILITE V-02-L2, manufactured by | |
| Nisshinbo Holdings, Inc.; solids content: 10% by mass) | |
| Oxazoline compound (crosslinking agent) (trade name: | 3.0 parts by mass |
| EPOCROS WS700, manufactured by Nippon Shokubai | |
| Co., Ltd.; solids content: 25% by mass) | |
| Surfactant (trade name: NAROACTY CL95, | 15.0 parts by mass |
| manufactured by Sanyo Chemical Industries, Ltd.; | |
| solids content: 1% by mass) | |
| Distilled water | 924.0 parts by mass |

—Formation of Surface Undercoat Layer—

A coating liquid for surface undercoat layer formation thus obtained was applied on one surface of a PET substrate (the surface opposite to the surface where the undercoat layer and polymer layer were provided), such that the amount of binder in terms of the amount of application was 0.1 g/m², and the coating liquid was dried for one minute at 180° C. Thus, a surface undercoat layer having a dry thickness of about 0.1 μm was formed.

Further, the reflective layer described below in Example 30 was applied on the surface undercoat layer. Thus, a back sheet sample for a solar cell was produced.

### Example D

An aluminum foil having a thickness of 20 μm was adhered on the surface opposite to the surface where the undercoat layer and polymer layer were provided under following condition.

Further, a white PET film (containing an amount of titanium dioxide white pigment of 14% by mass and the optical reflectivity is 82% at a wavelength of 550 nm) having a thickness of 75 μm was adhered on the aluminum foil under the same condition.

Based on the processes described above, a back sheet for solar cells having a laminate structure of polymer sheet of Example A/aluminum foil/white PET film was formed.

(Conditions for Adhesion)

The substrate 2 and the substrate 1 were adhered by hot pressing with a vacuum laminator (a vacuum laminating machine, manufactured by Nisshinbo Holdings, Inc.), using a mixture obtained by mixing an adhesive (trade name: LX660(K), manufactured by DIC Corp.) with 10 parts of a curing agent (trade name: KW75, manufactured by DIC Corp.).

Adhesion was carried out by drawing a vacuum at 80° C. for 3 minutes, and then pressing for 2 minutes. Thereafter, the assembly was maintained at 40° C. for 4 days, and thus the reaction was completed.

### Example E

Example E was carried out in the same manner as in Example D, except that the aluminum foil was changed to a silicon oxide deposited PET sheet having a thickness of 12 μm.

<Evaluation Method>

—Retention Rate of Breaking Elongation—

The retention rate of breaking elongation (%) represented by the following formula was calculated for the samples thus obtained, based on the measurement values, L0 and L1, of breaking elongation obtained by the measurement method shown below. A retention rate of breaking elongation of 50% or greater was considered acceptable in terms of practical use.

Retention rate of breaking elongation (%)=L1/L0×100

(Method for Measuring Breaking Elongation)

Samples A and B for measurement were prepared by cutting samples to a size of 10 mm in width×200 mm in length.

Sample A was humidified for 24 hours in an atmosphere at 25° C. and 60% RH, and then was subjected to a tensile test with a Tensilon (trade name: RTC-1210A, manufactured by Orientec Co., Ltd.). The length of the sample to be stretched was 10 cm, and the tensile rate was 20 mm/min. The breaking elongation of the sample A obtained by this evaluation was designated as L0.

Separately, sample B was subjected to a heat and moisture treatment for 50 hours in an atmosphere of 120° C. and 100% RH, and then was subjected to a tensile test in the same manner as in the case of the sample A. The breaking elongation of the sample B in this case was designated as L1.

—Evaluation of Adhesiveness—

(1) Adhesiveness Before a Lapse of Time Under Heat and Moisture

The surface of the fluorine-containing polymer layer of a sample was cut with a single-blade razor, 6 lines each in the length and width directions at an interval of 3 mm, and thus 25-mesh grids were formed. A Mylar tape (polyester adhesive tape) was attached thereon, and the tape was peeled by pulling manually in the 180° C. direction along the sample surface. At this time, the number of peeled mesh grids was counted, and thereby the adhesive force of the back layer was rated according to the following evaluation criteria. Evaluation grades 4 and 5 are considered acceptable in terms of practical use.

<Evaluation Criteria>

5: There are no peeled mesh grids (0 meshes).

4: The number of peeled mesh grids is from 0 to less than 0.5.

3: The number of peeled mesh grids is from 0.5 to less than 2.

2: The number of peeled mesh grids is from 2 to less than 10.

1: The number of peeled mesh grids is 10 or larger.

(2) Adhesiveness after a Lapse of Time Under Heat and Moisture

A sample was maintained in an environment of 120° C. and 100% RH for 48 hours, and then was humidified for one hour in an environment of 25° C. and 60% RH. Thereafter, the adhesive force of the fluorine-containing polymer layer was evaluated by the same method as that used in the evaluation of “(1) Adhesiveness before a lapse of time under heat and moisture”.

—Evaluation of Durability—

A sample was maintained under an atmosphere of 120° C. and 100% RH for 50 hours, and then the surface of the fluorine-containing polymer layer was observed with the naked eye and with an optical microscope (trade name: ME-600, manufactured by Nikon Corporation; magnification 100 times). The results were rated as follows.

Evaluation grades 3, 4 and 5 are considered acceptable in terms of practical use.

<Evaluation Criteria>

5: No change is recognized in the surface even under an optical microscopic observation.

4: When observed with an optical microscope, slight cracks or deformations are observed at the surface.

3: When observed with the naked eye, it may be seen that the surface has lost glossiness.

2: Slight cracks are observed under an observation with the naked eye.

1: Cracks are observed over the entire surface even under an observation with the naked eye.

—Evaluation of Surface State—

The surface state of the polymer sheets produced as described above was visually observed, and the samples were evaluated according to the following evaluation criteria. Among these, evaluation grades 3, 4 and 5 are considered acceptable in terms of practical use.

<Evaluation Criteria>

5: No unevenness or cissing is observed.

4: Very slight unevenness is observed, but no cissing is recognized.

3: Slight unevenness is observed, but no cissing is recognized.

2: Unevenness is clearly recognized, and some cissing is observed (fewer than 10 sites/m²)

1: Unevenness is clearly recognized, and cissing is observed at 10 or more sites/m².

TABLE 1

| | | Undercoat layer | | | | Polymer layer | | | |
|---|---|---|---|---|---|---|---|---|---|
| | | Binder | Thickness | Crosslinking agent | | Binder | Thickness | Crosslinking agent | |
| Sample | Support | Kind | [μm] | Kind | [%] | Kind | [μm] | Kind | [%] |
| Example 1 | PET-1 | P-1 | 3 | A-1 | 10 | P-101 | 2 | A-1 | 10 |
| Comparative | PET-1 | none | — | none | — | P-101 | 2 | A-1 | 10 |
| Example 1 | | | | | | | | | |
| Example 2 | PET-1 | P-1 | 0.1 | A-1 | 10 | P-101 | 2 | A-1 | 10 |
| Example 3 | PET-1 | P-1 | 0.5 | A-1 | 10 | P-101 | 2 | A-1 | 10 |
| Example 4 | PET-1 | P-1 | 1 | A-1 | 10 | P-101 | 2 | A-1 | 10 |
| Example 5 | PET-1 | P-1 | 5 | A-1 | 10 | P-101 | 2 | A-1 | 10 |
| Example 6 | PET-1 | P-1 | 10 | A-1 | 10 | P-101 | 2 | A-1 | 10 |
| Comparative | PET-1 | P-1 | 15 | A-1 | 10 | P-101 | 2 | A-1 | 10 |
| Example 2 | | | | | | | | | |
| Example 7 | PET-1 | P-1 | 3 | none | — | P-101 | 2 | A-1 | 10 |
| Example 8 | PET-1 | P-1 | 3 | A-1 | 1 | P-101 | 2 | A-1 | 10 |
| Example 9 | PET-1 | P-1 | 3 | A-1 | 2 | P-101 | 2 | A-1 | 10 |
| Example 10 | PET-1 | P-1 | 3 | A-1 | 5 | P-101 | 2 | A-1 | 10 |
| Example 11 | PET-1 | P-1 | 3 | A-1 | 20 | P-101 | 2 | A-1 | 10 |
| Example 12 | PET-1 | P-1 | 3 | A-1 | 25 | P-101 | 2 | A-1 | 10 |
| Example 13 | PET-1 | P-1 | 3 | A-1 | 30 | P-101 | 2 | A-1 | 10 |
| Comparative | PET-1 | P-1 | 3 | A-1 | 10 | P-101 | 0.3 | A-1 | 10 |
| Example 3 | | | | | | | | | |
| Example 14 | PET-1 | P-1 | 3 | A-1 | 10 | P-101 | 1 | A-1 | 10 |
| Example 15 | PET-1 | P-1 | 3 | A-1 | 10 | P-101 | 5 | A-1 | 10 |
| Example 16 | PET-1 | P-1 | 3 | A-1 | 10 | P-101 | 10 | A-1 | 10 |
| Comparative | PET-1 | P-1 | 3 | A-1 | 10 | P-101 | 15 | A-1 | 10 |
| Example 4 | | | | | | | | | |
| Example 17 | PET-1 | P-1 | 3 | A-1 | 10 | P-101 | 2 | none | — |
| Example 18 | PET-1 | P-1 | 3 | A-1 | 10 | P-101 | 2 | A-1 | 1 |
| Example 19 | PET-1 | P-1 | 3 | A-1 | 10 | P-101 | 2 | A-1 | 2 |
| Example 20 | PET-1 | P-1 | 3 | A-1 | 10 | P-101 | 2 | A-1 | 5 |
| Example 21 | PET-1 | P-1 | 3 | A-1 | 10 | P-101 | 2 | A-1 | 20 |
| Example 22 | PET-1 | P-1 | 3 | A-1 | 10 | P-101 | 2 | A-1 | 30 |
| Example 23 | PET-1 | P-2 | 3 | A-1 | 10 | P-101 | 2 | A-1 | 10 |
| Example 24 | PET-1 | P-3 | 3 | A-1 | 10 | P-101 | 2 | A-1 | 10 |
| Example 25 | PET-1 | P-4 | 3 | A-1 | 10 | P-101 | 2 | A-1 | 10 |
| Example 26 | PET-1 | P-11 | 3 | A-1 | 10 | P-101 | 2 | A-1 | 10 |
| Example 27 | PET-1 | P-1 | 3 | A-1 | 10 | P-102 | 2 | A-1 | 10 |
| Example 28 | PET-1 | P-1 | 3 | A-1 | 10 | P-103 | 2 | A-1 | 10 |
| Comparative | PET-1 | P-1 | 3 | A-1 | 10 | P-201 | 2 | A-1 | 10 |
| Example 5 | | | | | | | | | |
| Example 29 | PET-1 | P-1 | 3 | A-2 | 10 | P-101 | 2 | A-2 | 10 |

P-1: CERANATE WSA-1070 (trade name, manufactured by DIC Corporation)
P-2: CERANATE WSA-1060 (trade name, manufactured by DIC Corporation)
P-3: CHEMIPEARL S75N (trade name, manufactured by Mitsui Chemicals, Inc.)
P-4: JURYMER ET-410 (trade name, manufactured by Nihon Junyaku Co., Ltd.)
P-11: HYDRAN HW340 (trade name, manufactured by DIC Corporation), urethane 25%
P-101: OBBLIGATO SW0011F (trade name, manufactured by AGC Coat-Tech Co., Ltd.)
P-102: OBBLIGATO PW-402 (trade name, manufactured by AGC Coat-Tech Co., Ltd.)
P-103: OBBLIGATO PWD-100 (trade name, manufactured by AGC Coat-Tech Co., Ltd.)
P-201: HYDRAN HW340 (trade name, manufactured by DIC Corporation), urethane 25%

Here, the compositions of the respective binders are as follows.

P-1 represents an acrylic/silicone-based resin having a polysiloxane content of 30% and a solids content of 40%.

P-2 represents an acrylic/silicone-based resin having a polysiloxane content of 75% and a solids content of 35%.

P-3 represents an ethylene-unsaturated carboxylic acid copolymer having an unsaturated carboxylic acid content of 20% by weight and a solids content of 35%.

P-4 represents a polyacrylic acid ester having a solids content of 30%.

P-101 represents a fluorine-based resin having a solids content of 40%.

P-102 represents a fluorine-based resin having a solids content of 40%.

P-103 represents a fluorine-based resin having a solids content of 40%.

P-11 and P-201 represent a polyurethane resin having a solids content of 25%.

TABLE 2
Performance evaluation results

| | Retention rate | Adhesiveness before | Adhesiveness after | | |
|---|---|---|---|---|---|
| | of breaking | a lapse of time under | a lapse of time under | | Surface |
| Sample | elongation (%) | heat and moisture | heat and moisture | Durability | state |
| Example 1 | 74 | 5 | 5 | 5 | 5 |
| Comparative Example 1 | 74 | 1 | 1 | 5 | 5 |
| Example 2 | 74 | 5 | 5 | 5 | 5 |
| Example 3 | 74 | 5 | 5 | 5 | 5 |
| Example 4 | 74 | 5 | 5 | 5 | 5 |
| Example 5 | 74 | 5 | 5 | 5 | 5 |
| Example 6 | 74 | 5 | 5 | 5 | 5 |
| Comparative Example 2 | 74 | 5 | 5 | 5 | 2 |
| Example 7 | 74 | 4 | 3 | 5 | 5 |
| Example 8 | 74 | 5 | 5 | 5 | 5 |
| Example 9 | 74 | 5 | 5 | 5 | 5 |
| Example 10 | 74 | 5 | 5 | 5 | 5 |
| Example 11 | 74 | 5 | 5 | 5 | 5 |
| Example 12 | 74 | 5 | 5 | 5 | 5 |
| Example 13 | 74 | 5 | 5 | 5 | 3 |
| Comparative Example 3 | 74 | 5 | 5 | 2 | 5 |
| Example 14 | 74 | 5 | 5 | 5 | 5 |
| Example 15 | 74 | 5 | 5 | 5 | 5 |
| Example 16 | 74 | 5 | 5 | 5 | 5 |
| Comparative Example 4 | 74 | 5 | 5 | 5 | 2 |
| Example 17 | 74 | 5 | 4 | 5 | 5 |
| Example 18 | 74 | 5 | 5 | 5 | 5 |
| Example 19 | 74 | 5 | 5 | 5 | 5 |
| Example 20 | 74 | 5 | 5 | 5 | 5 |
| Example 21 | 74 | 5 | 5 | 5 | 5 |
| Example 22 | 74 | 5 | 5 | 5 | 4 |
| Example 23 | 74 | 4 | 4 | 5 | 4 |
| Example 24 | 74 | 5 | 5 | 5 | 4 |
| Example 25 | 74 | 5 | 5 | 5 | 4 |
| Example 26 | 74 | 5 | 3 | 5 | 4 |
| Example 27 | 74 | 5 | 5 | 5 | 4 |
| Example 28 | 74 | 5 | 5 | 5 | 4 |
| Comparative Example 5 | 74 | 5 | 5 | 1 | 4 |
| Example 29 | 74 | 5 | 5 | 5 | 4 |

As shown in Table 2, Examples 1 to 29 were rated as grade 4 in all of the evaluation items, and it was found that the polymer sheet samples (polymer sheets for solar cell back sheets) of Examples 1 to 29 are all suitable for the use as back sheets for solar cells.

### Example 30

The polymer sheet sample obtained in Example 1 was used to produce a back sheet for solar cells, by providing a reflective layer to the polymer sheet by the method shown below.

<Reflective Layer>

—Preparation of Coating Liquid for Reflective Layer Formation—

The various components of the following composition were mixed, and thus a coating liquid for reflective layer formation was prepared.

(Composition of Coating Liquid)

| | |
|---|---|
| Titanium dioxide dispersion used in Example 1 | 714.3 parts by mass |
| Aqueous dispersion liquid of polyacrylic resin (trade | 171.4 parts by mass |
| name: JURYMER ET410, binder, manufactured by | |
| Nihon Junyaku Co., Ltd.; solids content: 30%) | |
| Polyoxyalkylene alkyl ether (trade name: NAROACTY | 26.8 parts by mass |
| CL95, manufactured by Sanyo Chemical Industries, | |
| Ltd.; solids content: 1%) | |
| Oxazoline compound (trade name: EPOCROS WS-700, | 17.9 parts by mass |
| crosslinking agent, manufactured by Nippon Shokubai | |
| Co., Ltd.; solids content: 25%) | |
| Distilled water | 69.6 parts by mass |

—Formation of Reflective Layer—

The coating liquid thus obtained was applied on the surface opposite to the surface where the undercoat layer and the fluorine-containing polymer layer were provided on the PET substrate, and was dried for one minute at 180° C. Thus, a reflective layer having an amount of titanium dioxide of 5.5 g/m² and a thickness of about 2 μm was formed.

Based on the processes described above, a back sheet for solar cells having a laminate structure of reflective layer/PET substrate/undercoat layer/fluorine-containing polymer layer was formed.

### Example 31

A reinforced glass plate having a thickness of 3 mm, an EVA sheet (trade name: SC50B, manufactured by Mitsui Chemical Fabro, Inc.), a crystalline photovoltaic cell, an EVA sheet (trade name: SC50B, manufactured by Mitsui Chemical Fabro, Inc.), and the sample sheets (back sheets for solar cells) of Examples 30, C, D or E were superimposed in this order, and the assembly was hot pressed using a vacuum laminator (vacuum laminating machine, manufactured by Nisshinbo Holdings, Inc.). Accordingly, the reinforced glass, photovoltaic cell, and sample sheet were respectively adhered to EVA. In this case, the sample sheet was arranged such that the reflective layer was in contact with the EVA sheet.

The adhesion conditions for the EVA were as follows.

The assembly was subjected to a vacuum at 128° C. for 3 minutes using a vacuum laminator, and then provisional adhesion was achieved by pressing for 2 minutes. Thereafter, the assembly was subjected to a main adhesion treatment in a dry oven at 150° C. for 30 minutes.

As such, four types of crystal-based solar cell module containing Examples 30, C, D or E as back sheets were produced. The solar cell module thus produced was used to perform power generation, and the solar cell module exhibited satisfactory power generation performance as a solar cell.

<Production of Polymer Substrate>

—Production of PET-2—

[Step 1]

100 parts by mass of dimethyl terephthalate, trimethyl trimellitate (added to achieve a molar ratio of dimethyl terephthalate/trimethyl trimellitate=99.7/0.3), 57.5 parts by mass of ethylene glycol, 0.06 parts by mass of magnesium acetate, and 0.03 parts by mass of antimony trioxide were melted at 150° C. in a nitrogen atmosphere, and while the mixture was stirred, the temperature was increased to 230° C. over 3 hours. Methanol was distilled off, and thus a transesterification reaction was completed.

[Step 2]

After completion of the transesterification reaction, an ethylene glycol solution prepared by dissolving 0.019 parts by mass (equivalent to 1.9 mol/t) of phosphoric acid and 0.027 parts by mass (equivalent to 1.5 mol/t) of sodium dihydrogen phosphate dihydrate in 0.5 parts by mass of ethylene glycol, was added to the system.

[Step 3]

A polymerization reaction was carried out at an end-point temperature of 285° C. and a degree of vacuum of 0.1 Torr, and thus a polyester (polyethylene terephthalate) having an intrinsic viscosity of 0.54 and a number of terminal carboxyl groups of 13 mol/ton was obtained.

[Step 4]

The polyethylene terephthalate thus obtained was dried for 6 hours at 160° C. and was crystallized. Subsequently, solid state polymerization was carried out at 220° C. and at a degree of vacuum of 0.3 Torr for 9 hours, and thus a polyester having an intrinsic viscosity of 0.90, a number of terminal carboxyl groups of 12 mol/ton, a melting point of 255° C., and a glass transition temperature Tg of 83° C. was obtained.

[Step 5]

One part by weight of a polycarbodiimide (trade name: STABAXOL P100″, manufactured by Rhein Chemie Rheinau GmbH) was added to 99 parts by weight of the polyester obtained in Step 4, and the mixture was compounded.

[Step 6]

The compounded product obtained as described above was subjected to drying under reduced pressure for 2 hours under the conditions of a temperature of 180° C. and a degree of vacuum of 0.5 mmHg, and the dried product was supplied to an extruder which had been heated to 297° C. Foreign materials were filtered using a 50-μm cutoff filter, and then the compounded product was introduced into a T-die nozzle. Subsequently, the compounded product was extruded through the T-die nozzle into a sheet form, and thus a molten single-layer sheet was obtained. The molten single-layer sheet was adhered onto a drum which had been maintained at a surface temperature of 20° C., by an electrostatic application method, and the molten single-layer sheet was cooled and solidified. Thus, an unstretched single layer film was obtained.

[Step 7]

Subsequently, the unstretched single-layer film thus obtained was preheated using a group of heated rolls, and then MD stretching 1 was carried out to 1.8 times at a temperature of 80° C., followed by MD stretching 2 to 2.3 times at a temperature of 95° C. Stretching was carried out to 4.1 times in total in the longitudinal direction (MD), and then the film was cooled with a group of rolls at a temperature of 25° C. Thus, a uniaxially stretched film was obtained. While two edges of the uniaxially stretched film thus obtained were clamped with clips, the uniaxially stretched film was led into a preheating zone at a temperature of 95° C. in a tenter, and subsequently, the film was continuously stretched to 4.0 times in the width direction (TD), which was perpendicular to the longitudinal direction, in a heating zone at a temperature of 100° C.

[Step 8]

Subsequently, the film was subjected to a heat treatment for 20 seconds at a temperature of 205° C. (first heat treatment temperature) in a heat treatment zone in the tenter. Subsequently, the film was relaxed at a relaxation ratio of 3% in the width direction (TD) at a temperature of 180° C., and by reducing the clip interval of the tenter, the film was relaxed at a relaxation ratio of 1.5% in the longitudinal direction (MD). Subsequently, the film was uniformly cooled to 25° C., and then was rolled. Thus, a biaxially stretched polyester film (PET-2) having a thickness of 250 μm was obtained.

The results of an evaluation of the characteristics of PET-2 are presented below.
Content of terminal carboxyl groups: 5 eq/t
Tmeta: 190° C.
Average elongation retention ratio: 49%
Plane orientation coefficient: 0.170
Intrinsic viscosity: 0.75 dl/g
Thermal shrinkage ratio (MD/TD): 0.4%/0.2%
Content of constituent component (p): 0.15 mol %
Buffering agent: Sodium dihydrogen phosphate 1.5 mol/t
Terminal blocking agent: Polycarbodiimide 1 wt %
Content of phosphorus atoms: 230 ppm

—Production of PET-3—

A biaxially stretched polyester film (PET-3) was produced by the same method as that used for PET-2, except that the first heat treatment temperature used in the [Step 8] of the method for producing PET-2 was changed to 230° C.

The characteristics of PET-3 were evaluated, and as compared with PET-2, Tmeta changed to 225° C., and the average elongation retention ratio changed to 7%.

—Production of PET-4—

A biaxially stretched polyester film (PET-4) was produced by the same method as that used for PET-2, except that the thickness was changed to 75 μm.

The characteristics of PET-3 were evaluated, and as compared with PET-2, Tmeta changed to 190° C., and the average elongation retention ratio changed to 50%.

### Example 41

These PET supports were used to produce polymer sheets which had, on one surface of each support, an “undercoat layer” and a “polymer layer” in an order closer to the support.

[Corona Treatment]

One surface of the support was corona treated under the following conditions.

Apparatus: Solid state corona treating machine, 6-KVA model, manufactured by Pillar Corp.

Gap clearance between electrode and dielectric roll: 1.6 mm

Treatment frequency: 9.6 kHz

Treatment rate: 20 m/min

Treatment intensity: 0.375 kV·A·min/m²

[Undercoat Layer]

—Preparation of Pigment Dispersion—

Various components of the following composition were mixed, and the mixture was subjected to a dispersion treatment for one hour using a Dyno Mill type dispersing machine.

(Composition of Pigment Dispersion)

| | |
|---|---|
| Titanium dioxide (volume average particle size = 0.42 μm) | 40 mass% |
| (trade name: TIPAQUE R-780-2, manufactured by Ishihara | |
| Sangyo Kaisha, Ltd.; solids content 100% by mass) | |
| Aqueous solution of polyvinyl alcohol (10 mass%) (trade | 20.0 mass% |
| name: PVA-105, manufactured by Kuraray Co., Ltd.) | |
| Surfactant (trade name: DEMOL EP, manufactured by | 0.5 mass% |
| Kao Corp.; solids content: 25% by mass) | |
| Distilled water | 39.5 mass% |

—Preparation of Coating Liquid for Undercoat Layer Formation—

Various components of the following composition were mixed, and thus a coating liquid for undercoat layer formation was prepared.

(Composition of Coating Liquid)

| | |
|---|---|
| Binder (P-1) (trade name: CERANATE WSA-1070, | 362.3 parts by mass |
| manufactured by DIC Corp., solids content: 40% by | |
| mass) | |
| Carbodiimide compound (crosslinking agent) (trade | 36.2 parts by mass |
| name: CARBODILITE V-02-L2, manufactured by | |
| Nisshinbo Holdings, Inc.; solids content: 40% by mass) | |
| Surfactant (trade name: NAROACTY CL95, | 9.7 parts by mass |
| manufactured by Sanyo Chemical Industries, Ltd.; | |
| solids content: 1% by mass) | |
| Dispersion described above | 157.0 parts by mass |
| Distilled water | 434.8 parts by mass |

—Formation of Undercoat Layer—

The coating liquid for undercoat layer formation thus obtained was applied on the corona-treated surface of the support, such that the amount of binder in terms of the amount of application was 3.0 g/m², and the coating liquid was dried for one minute at 180° C. Thus, an undercoat layer having a dry thickness of about 3 μm was formed.

[Polymer Layer]

—Preparation of Coating Liquid for Polymer Layer Formation—

Various components of the following composition were mixed, and thus a coating liquid for polymer layer formation was prepared.

(Composition of Coating Liquid)

| | |
|---|---|
| Fluorine-based binder (P-100) (trade name: | 362.3 parts by mass |
| OBBLIGATO SW0011F, manufactured by AGC | |
| Coat-Tech Co., Ltd.; solids content: 40% by mass) | |
| Carbodiimide compound (crosslinking agent) (trade | 24.2 parts by mass |
| name: CARBODILITE V-02-L2, manufactured by | |
| Nisshinbo Holdings, Inc.; solids content: 40% by mass) | |
| Surfactant (trade name: NAROACTY CL95, | 24.2 parts by mass |
| manufactured by Sanyo Chemical Industries, Ltd.; | |
| solids content: 1% by mass) | |
| Distilled water | 703.8 parts by mass |

—Formation of Polymer Layer—

The coating liquid for polymer layer formation thus obtained was applied on the undercoat layer, such that the amount of binder in terms of the amount of application was 2.0 g/m², and the coating liquid was dried for one minute at 180° C. Thus, a fluorine-containing polymer layer having a dry thickness of about 2 μm was formed.

The sample thus obtained was subjected to the following evaluations, and the results of evaluations are presented in Table 3.

<Evaluations>

—1. Adhesiveness—

[A] Adhesiveness Before Time Lapse in Hot and Humid Environment.

The surface of a sample where a polymer layer is formed is given, using a razor, 6 cuts each in the vertical and horizontal directions at an interval of 3 mm. A Mylar tape having a width of 20 mm is attached thereon, and the tape is rapidly peeled in the 180° C. direction. The number of peeled mesh grids is counted, and thereby adhesiveness is rated according to the following evaluation criteria.

5: No peeling occurs.

4: There are zero peeled mesh grids, but scratched areas have been slightly peeled.

3: The number of peeled mesh grids is less than 1.

2: The number of peeled mesh grids is from 1 to 5.

1: The number of peeled mesh grids is 5 or larger.

Evaluation grades 3, 4 and 5 are considered acceptable in terms of practical application.

[B] Adhesiveness after Time Lapse in Hot and Humid Environment

The sample for adhesion evaluation thus obtained was stored in an environment of 120° C. and 100% RH for 48 hours (a lapse of time under a hot and moisture), and then the adhesive force was measured by the same method as that used in section [A]. The ratio of the measured adhesive force after the storage, was calculated with respect to the [A] adhesive force prior to the lapse of time under a hot and moisture of the same sample for adhesion evaluation: [%=(Adhesive force after time lapse in hot and humid environment/[A] adhesive force before time lapse in a hot and humid environment)×100]. Furthermore, the adhesive force was evaluated by the same method as that used in section [A], based on the adhesive force measured after a lapse of time under a hot and moisture.

### Examples 42 to 47

Examples 42 to 47 were carried out in the same manner as in example 41, except that the binder of the undercoat layer was changed as indicated in Table 3. The samples thus obtained were subjected to the same evaluation as in Example 41, and the results are presented in Table 3.

### Examples 48 to 55

Examples 48 to 55 were carried out in the same manner as in Example 41, except that the thicknesses of the undercoat layer and the polymer layer were changed as indicated in Table 3. The samples thus obtained were subjected to the same evaluation as in Example 41, and the results are presented in Table 3.

### Examples 56 to 60

Examples 55 to 60 were carried out in the same manner as in Example 41, except that the method of surface treatment was changed as indicated in Table 3. The samples thus obtained were subjected to the same evaluation as in Example 41, and the results are presented in Table 3.

### Example 56

### No Surface Treatment

### Example 57

### Following Flame Treatment

[Flame Treatment Conditions]

While PET-2 was conveying, the surface of PET-2 was irradiated for 0.5 seconds with a flame obtained by combusting a gas of propane gas and air mixed at a ratio of 1/17 (volume ratio) using a horizontally long type burner.

### Example 58

### Following Ultraviolet Radiation Treatment

[Ultraviolet Treatment Conditions]

While PET-2 was conveying, the surface of PET-2 was irradiated under the atmospheric pressure for 20 seconds with ultraviolet radiation generated using a low pressure mercury lamp.

### Example 59

### Following Vacuum Plasma Treatment

[Vacuum Plasma Treatment Conditions]

While PET-2 was conveying, the surface of PET-2 was irradiated for 15 seconds with plasma at an output power of 1000 W·min/m² generated by a discharge using a 3.56-MHz high frequency discharge apparatus, in an atmosphere of a plasma gas of a mixture of oxygen gas and argon gas at a ratio of 80/20 (gas pressure: 1.5 Torr).

### Example 60

### Following Atmospheric Plasma Treatment

While PET-2 was conveying, the surface of PET-2 was irradiated for 15 seconds with plasma at an output power of 500 W·min/m² generated by a discharge using a 3.56-MHz high frequency discharge apparatus, in an atmosphere of a plasma gas of a mixture of oxygen gas and argon gas at a ratio of 80/20 (gas pressure: 1.5 Torr).

### Example 61

Example 61 was carried out in the same manner as in Example 41, except that PET-3 was used instead of PET-2. The sample thus obtained was subjected to the same evaluation as in Example 41, and the results are presented in Table 3.

### Comparative Example 11

Comparative Example 11 was carried out in the same manner as in Example 41, except that the undercoat layer was not provided. The sample thus obtained was subjected to the same evaluation as that performed in Example 41, and the results are presented in Table 3.

TABLE 3

| | | | | | | | | | | Performance evaluation | |
|---|---|---|---|---|---|---|---|---|---|---|---|
| | | | | | | | | | | results | |
| | | | | | | | | | | | Adhesive- |
| | | Retention | | | | | | | | | ness |
| | | rate of | | Undercoat layer | | | | | | | after a lapse |
| | | elongation | Surface | Binder | | | | Polymer layer | | | or time under |
| | Support | at break | treatment | | | SP | Thickness | Binder | Thickness | | heat and |
| Sample | type | (%) | type | Type | | value | [μm] | type | [μm] | Adhesiveness | moisture |
| Example 41 | PET-2 | 49 | Corona | P-21 | Silicone-based | — | 3 | P-100 | 2 | 5 | 5 |
| Example 42 | PET-2 | 49 | Corona | P-22 | Acrylic-based | 10.8 | 3 | P-100 | 2 | 5 | 4 |
| Example 43 | PET-2 | 49 | Corona | P-23 | Polyester-based | 10.8 | 3 | P-100 | 2 | 5 | 4 |
| Example 44 | PET-2 | 49 | Corona | P-24 | Urethane resin | 10.7 | 3 | P-100 | 2 | 5 | 4 |
| Example 45 | PET-2 | 49 | Corona | P-25 | Acrylic-based | 9.5 | 3 | P-100 | 2 | 5 | 4 |
| Example 46 | PET-2 | 49 | Corona | P-26 | Acrylic resin | 9.2 | 3 | P-100 | 2 | 4 | 4 |
| Example 47 | PET-2 | 49 | Corona | P-27 | SBR rubber-based | 9.3 | 3 | P-100 | 2 | 3 | 3 |
| Example 48 | PET-2 | 49 | Corona | P-22 | Acrylic-based | 10.8 | 0.2 | P-100 | 2 | 5 | 5 |
| Example 49 | PET-2 | 49 | Corona | P-22 | Acrylic-based | 10.8 | 3 | P-100 | 2 | 5 | 5 |
| Example 50 | PET-2 | 49 | Corona | P-22 | Acrylic-based | 10.8 | 7 | P-100 | 2 | 5 | 5 |
| Example 51 | PET-2 | 49 | Corona | P-22 | Acrylic-based | 10.8 | 10 | P-100 | 2 | 5 | 4 |
| Example 52 | PET-2 | 49 | Corona | P-22 | Acrylic-based | 10.8 | 10 | P-100 | 0.8 | 4 | 4 |
| Example 53 | PET-2 | 49 | Corona | P-22 | Acrylic-based | 10.8 | 10 | P-100 | 5 | 5 | 5 |
| Example 54 | PET-2 | 49 | Corona | P-22 | Acrylic-based | 10.8 | 10 | P-100 | 9 | 5 | 5 |
| Example 55 | PET-2 | 49 | Corona | P-22 | Acrylic-based | 10.8 | 10 | P-100 | 12 | 4 | 4 |
| Example 56 | PET-2 | 49 | none | P-22 | Acrylic-based | 10.8 | 3 | P-100 | 2 | 5 | 5 |
| Example 57 | PET-2 | 49 | Flame | P-22 | Acrylic-based | 10.8 | 3 | P-100 | 2 | 5 | 5 |
| Example 58 | PET-2 | 49 | Ultraviolet | P-22 | Acrylic-based | 10.8 | 3 | P-100 | 2 | 5 | 5 |
| Example 59 | PET-2 | 49 | Vacuum | P-22 | Acrylic-based | 10.8 | 3 | P-100 | 2 | 5 | 5 |
| | | | Plasma | | | | | | | | |
| Example 60 | PET-2 | 49 | Atmospheric | P-22 | Acrylic-based | 10.8 | 3 | P-100 | 2 | 5 | 5 |
| | | | Plasma | | | | | | | | |
| Example 61 | PET-3 | 7 | Corona | P-22 | Acrylic-based | 10.8 | 3 | P-100 | 2 | 5 | 2 |
| Comparative | PET-2 | 49 | Corona | none | | — | — | P-100 | 2 | 2 | 1 |
| Example 11 | | | | | | | | | | | |

### Example 62

The sample (polymer sample) of Example 41 was subjected to the same corona treatment as that performed in Example 41, on the surface opposite to the surface where the polymer layer was provided, and the following surface undercoat layer and colored layer were provided on this surface. Thus, a back sheet sample was produced.

[Surface Undercoat Layer]

—Preparation of Coating Liquid for Surface Undercoat Layer Formation—

Various components of the following components were mixed, and thus a coating liquid for surface undercoat layer formation was prepared.

(Composition of Coating Liquid)

| | |
|---|---|
| Polyester binder (trade name: VYLONAL DM1245, | 48.0 parts by mass |
| manufactured by Toyobo Co., Ltd.; solids content | |
| 30% by mass) | |
| Carbodiimide compound (crosslinking agent) (trade | 10.0 parts by mass |
| name: CARBODILITE V-02-L2, manufactured by | |
| Nisshinbo Holdings, Inc.; solids content: 10% by mass) | |
| Oxazoline compound (crosslinking agent) (trade name: | 3.0 parts by mass |
| EPOCROS WS700, manufactured by Nippon Shokubai | |
| Co., Ltd.; solids content: 25% by mass) | |
| Surfactant (trade name: NAROACTY CL95, | 15.0 parts by mass |
| manufactured by Sanyo Chemical Industries, Ltd.; | |
| solids content: 1% by mass) | |
| Distilled water | 907.0 parts by mass |

—Formation of Surface Undercoat Layer—

A coating liquid for surface undercoat layer formation thus obtained was applied on one surface of a PET substrate (the surface opposite to the surface where the polymer layer was provided), such that the amount of binder in terms of the amount of application was 0.1 g/m², and the coating liquid was dried for one minute at 180° C. Thus, a surface undercoat layer having a dry thickness of about 0.1 μm was formed.

[Colored Layer]

—Preparation of Coating Liquid for Colored Layer Formation—

Various components of the following components were mixed, and thus a coating liquid for colored layer formation was prepared.

(Composition of Coating Liquid)

| | |
|---|---|
| Dispersion of titanium dioxide (same as that of Example | 80.0% by mass |
| 41) | |
| Silanol-modified polyvinyl alcohol binder (trade name: | 11.4% by mass |
| R1130, manufactured by Kuraray Co., Ltd.; solids | |
| content: 7% by mass) | |
| Polyoxyalkylene alkyl ether (trade name: NAROACTY | 3.0% by mass |
| CL95, manufactured by Sanyo Chemical Industries, Ltd.; | |
| solids content: 1% by mass) | |
| Oxazoline compound (trade name: EPOCROS WS700, | 2.0% by mass |
| manufactured by Nippon Shokubai Co., Ltd.; solids | |
| content: 25% by mass, crosslinking agent) | |
| Distilled water | 3.6% by mass |

—Formation of Colored Layer—

The coating liquid thus obtained was applied on one surface of the biaxially stretched PET, and the coating liquid was dried for one minute at 180° C. Thus, a colored layer having an amount of titanium dioxide of 7.0 g/m² and an amount of binder of 1.2 g/m² was formed.

<Production and Evaluation of Solar Cell Module>

A reinforced glass plate having a thickness of 3.2 mm, an EVA sheet (trade name: SC50B, manufactured by Mitsui Chemical Fabro, Inc.), a crystalline photovoltaic cell, an EVA sheet (trade name: SC50B, manufactured by Mitsui Chemical Fabro, Inc.), and a back sheet sample were superimposed in this order, and the layers were adhered to EVA by hot pressing the assembly using a vacuum laminator (a vacuum laminating machine manufactured by Nisshinbo Holdings, Inc.). However, the back sheet was disposed such that the colored layer was in contact with the EVA sheet. Furthermore, the conditions for EVA adhesion are as follows.

A vacuum was drawn at 128° C. for 3 minutes using a vacuum laminator, and then the assembly was subjected to provisional adhesion by pressing the assembly for 2 minutes. Thereafter, the assembly was subjected to a main adhesion treatment at 150° C. for 30 minutes in a dry oven.

As such, a crystalline solar cell module was produced. Solar cell modules thus produced were operated for power generation, and all exhibited satisfactory power generation performance as solar cells.

### Example 63

A polymer sheet sample was produced in the same manner as in Example 41, except that PET-4 was used as the support instead of PET-2. This sample, an aluminum foil having a thickness of 20 μm, a PET support having a thickness of 188 μm, and a white PET support having a thickness of 50 μm were adhered in this order, and thus a back sheet sample was produced.

At the time of adhesion, the support surface was preliminarily subjected to the same corona treatment as that performed in Example 41.

(Conditions for Adhesion)

The substrate 2 and the substrate 1 were adhered by hot pressing with a vacuum laminator (a vacuum laminating machine, manufactured by Nisshinbo Holdings, Inc.), using a mixture obtained by mixing an adhesive (trade name: LX660(K), manufactured by DIC Corp.) with 10 parts of a curing agent (trade name: KW75, manufactured by DIC Corp.).

Adhesion was carried out by drawing a vacuum at 80° C. for 3 minutes, and then pressing for 2 minutes. Thereafter, the assembly was maintained at 40° C. for 4 days, and thus the reaction was completed.

A solar cell module was produced by the same method as that used in Example 61, using this back sheet sample.

The solar cell modules thus produced were operated for power generation, and all exhibited satisfactory power generation performance as solar cells.

### Example 64

A solar cell module was produced in the same manner as in Example 63, except that a barrier layer-attached PET having a thickness of 12 μm was used instead of the aluminum foil.

The solar cell modules thus produced were operated for power generation, and all exhibited satisfactory power generation performance as solar cells.

The invention includes the following exemplary embodiments.
<1> A polymer sheet for a solar cell back sheet, comprising: a polymer support; an undercoat layer that contains a first binder and that is provided on at least one surface of the polymer support at a thickness of from 0.05 to 10 μm; and a fluorine-containing polymer layer that contains a second binder including at least a fluorine-based polymer and that is provided in contact with the undercoat layer of the at least one surface of the polymer support, at a thickness of from 0.8 to 12 nm.
<2> The polymer sheet for a solar cell back sheet of <1>, wherein the polymer support has: a terminal carboxyl group concentration of from 4.0 mol/ton to 15 mol/ton; a minor endothermic peak temperature Tmeta (° C.) of 220° C. or lower as determined by differential scanning calorimetry (DSC); and an average elongation retention ratio of 10% or greater after storage for 72 hours under conditions of a temperature of 125° C. and humidity of 100%.
<3> The polymer sheet for a solar cell back sheet of <1> or <2>, wherein the undercoat layer has a thickness of from 0.5 to 8.0 μm, and the first binder contained in the undercoat layer is a silicone resin, a polyolefin, or an acrylic resin, polyester resin or polyurethane resin having a solubility parameter of 9.5 to 14.0 (cal/cm³)^{0.5}.
<4> The polymer sheet for a solar cell back sheet of any one of <1> to <3>, wherein the first binder is a silicone resin.
<5> The polymer sheet for a solar cell back sheet of any one of <1> to <4>, wherein the undercoat layer contains a crosslinking agent in an amount of from 0.5% to 25% by mass relative to an amount of the first binder contained in the undercoat layer.
<6> The polymer sheet for a solar cell back sheet of any one of <1> to <5>, wherein the undercoat layer, the fluorine-containing polymer layer, or a combination thereof, has a crosslinked structure derived from a crosslinking agent.
<7> The polymer sheet for a solar cell back sheet of any one of <1> to <6>, wherein the undercoat layer contains a white pigment in an amount of from 4 g/m² to 12 g/m².
<8> The polymer sheet for a solar cell back sheet of any one of <1> to <7>, wherein the fluorine-containing polymer layer has a crosslinked structure derived from a crosslinking agent contained in an amount of from 0.5% to 25% by mass relative to an amount of the second binder contained in the fluorine-containing polymer layer.
<9> The polymer sheet for a solar cell back sheet of any one of <1> to <8>, wherein a value of breaking elongation obtainable after storage for 50 hours under conditions of 120° C. and 100% RH is 50% or greater of a value of breaking elongation before storage.
<10> The polymer sheet for a solar cell back sheet of any one of <1> to <9>, wherein the at least one surface of the polymer support on which the undercoat layer is provided is surface treated.
<11> A back sheet for a solar cell, comprising the polymer sheet for a solar cell back sheet of any one of <1> to <10>.
<12> The back sheet for a solar cell of <11>, wherein the fluorine-containing polymer layer is disposed as an outermost layer.
<13> The back sheet for a solar cell of <11> or <12>, wherein a colored layer is provided on one surface of the polymer support.
<14> The back sheet for a solar cell of any one of <11> to <13>, wherein a readily adhesive layer having an adhesive power of 5 N/cm or greater with respect to a sealing material is provided on a surface of the polymer support opposite to the surface on which the fluorine-containing polymer layer is provided.
<15> The back sheet for a solar cell of any one of <11> to <14>, further comprising a barrier layer or a metal sheet.
<16> The back sheet for a solar cell of any one of <11> to <15>, wherein another polymer sheet is attached, via an adhesive, to a surface opposite to the surface where the fluorine-containing polymer layer of the polymer sheet is formed.
<17> A solar cell module comprising the back sheet for a solar cell of any one of <11> to <16>.
<18> A method of producing the polymer sheet for a solar cell back sheet of any one of <1> to <10>, the method comprising: providing a polymer sheet having the undercoat layer on at least one surface of the polymer support; applying a coating liquid, which contains the second binder containing the fluorine-based polymer and contains water in an amount of 60% by mass or greater relative to a total amount of solvent, on the undercoat layer; and forming the fluorine-containing polymer layer by drying the coating liquid applied on the undercoat layer.
<19> The method of producing the polymer sheet for a solar cell back sheet of <18>, wherein the providing of a polymer sheet comprises applying a coating liquid containing the first binder on at least one surface of the polymer support; and drying the coating liquid containing the first binder on the polymer support.
<20> The method of producing the polymer sheet for a solar cell back sheet of <18> or <19>, wherein the forming of the fluorine-containing polymer layer comprises drying the coating liquid applied on the undercoat layer to form the fluorine-containing polymer layer, and then curing the fluorine-containing polymer layer.

All publications, patent applications, and technical standards mentioned in this specification are herein incorporated by reference to the same extent as if each individual publication, patent application, or technical standard was specifically and individually indicated to be incorporated by reference.

What is claimed is:

1. A polymer sheet for a solar cell back sheet, comprising:
a polymer support;
an undercoat layer that contains a first binder and that is provided on at least one surface of the polymer support at a thickness of from 0.05 to 10 μm; and
a fluorine-containing polymer layer that contains a second binder including at least a fluorine-based polymer and that is provided in contact with the undercoat layer of the at least one surface of the polymer support, at a thickness of from 0.8 to 12 μm.

2. The polymer sheet for a solar cell back sheet of claim 1, wherein the polymer support has: a terminal carboxyl group concentration of from 4.0 mol/ton to 15 mol/ton; a minor endothermic peak temperature Tmeta (° C.) of 220° C. or lower as determined by differential scanning calorimetry (DSC); and an average elongation retention ratio of 10% or greater after storage for 72 hours under conditions of a temperature of 125° C. and humidity of 100%.

3. The polymer sheet for a solar cell back sheet of claim 1, wherein the undercoat layer has a thickness of from 0.5 to 8.0 μm, and the first binder contained in the undercoat layer is a silicone resin, a polyolefin, or an acrylic resin, polyester resin or polyurethane resin having a solubility parameter of 9.5 to 14.0 (cal/cm³)^{0.5}.

4. The polymer sheet for a solar cell back sheet of claim 1, wherein the first binder is a silicone resin.

5. The polymer sheet for a solar cell back sheet of claim 1, wherein the undercoat layer contains a crosslinking agent in an amount of from 0.5% to 25% by mass relative to an amount of the first binder contained in the undercoat layer.

6. The polymer sheet for a solar cell back sheet of claim 1, wherein the undercoat layer, the fluorine-containing polymer layer, or a combination thereof, has a crosslinked structure derived from a crosslinking agent.

7. The polymer sheet for a solar cell back sheet of claim 1, wherein the undercoat layer contains a white pigment in an amount of from 4 g/m² to 12 g/m².

8. The polymer sheet for a solar cell back sheet of claim 1, wherein the fluorine-containing polymer layer has a crosslinked structure derived from a crosslinking agent contained in an amount of from 0.5% to 25% by mass relative to an amount of the second binder contained in the fluorine-containing polymer layer.

9. The polymer sheet for a solar cell back sheet of claim 1, wherein a value of breaking elongation obtainable after storage for 50 hours under conditions of 120° C. and 100% RH is 50% or greater of a value of breaking elongation before storage.

10. The polymer sheet for a solar cell back sheet of claim 1, wherein the at least one surface of the polymer support on which the undercoat layer is provided is surface treated.

11. A back sheet for a solar cell, comprising the polymer sheet for a solar cell back sheet of claim 1.

12. The back sheet for a solar cell of claim 11, wherein the fluorine-containing polymer layer is disposed as an outermost layer.

13. The back sheet for a solar cell of claim 11, wherein a colored layer is provided on one surface of the polymer support.

14. The back sheet for a solar cell of claim 11, wherein a readily adhesive layer having an adhesive power of 5 N/cm or greater with respect to a sealing material is provided on a surface of the polymer support opposite to the surface on which the fluorine-containing polymer layer is provided.

15. The back sheet for a solar cell of claim 11, further comprising a barrier layer or a metal sheet.

16. The back sheet for a solar cell of claim 11, wherein another polymer sheet is attached, via an adhesive, to a surface opposite to the surface where the fluorine-containing polymer layer of the polymer sheet is formed.

17. A solar cell module comprising the back sheet for a solar cell of claim 11.

18. A method of producing the polymer sheet for a solar cell back sheet of claim 1, the method comprising:
providing a polymer sheet having the undercoat layer on at least one surface of the polymer support;
applying a coating liquid, which contains the second binder containing the fluorine-based polymer and contains water in an amount of 60% by mass or greater relative to a total amount of solvent, on the undercoat layer; and
forming the fluorine-containing polymer layer by drying the coating liquid applied on the undercoat layer.

19. The method of producing the polymer sheet for a solar cell back sheet of claim 18, wherein the providing of a polymer sheet comprises applying a coating liquid containing the first binder on at least one surface of the polymer support; and drying the coating liquid containing the first binder on the polymer support.

20. The method of producing the polymer sheet for a solar cell back sheet of claim 18, wherein the forming of the fluorine-containing polymer layer comprises drying the coating liquid applied on the undercoat layer to form the fluorine-containing polymer layer, and then curing the fluorine-containing polymer layer.
